(19) United States
(12) Patent Application Publication
(10) Pub. No.: US 2025/0366329 A1
(43) Pub. Date: Nov. 27, 2025

(54) DISPLAY DEVICE AND MANUFACTURING METHOD THEREOF

(71) Applicant: Samsung Display Co., LTD., Yongin-si (KR)

(72) Inventors: Dong Hyun LEE, Yongin-si (KR); Youn Woong KANG, Yongin-si (KR); Si Joon SONG, Yongin-si (KR); Jun Young LEE, Yongin-si (KR); Dae Hyuk IM, Yongin-si (KR)

(73) Assignee: Samsung Display Co., LTD., Yongin-si (KR)

(21) Appl. No.: 19/169,453

(22) Filed: Apr. 3, 2025

(30) Foreign Application Priority Data
May 22, 2024 (KR) 10-2024-0066632

(51) Int. Cl. H10K 59/131; H05K 1/09; H10K 59/12; H10K 59/80; H10K 71/60

(52) U.S. Cl. CPC H10K 59/131; H05K 1/092; H10K 59/1201; H10K 59/805; H10K 71/60

(57) ABSTRACT

Provided is a display device including a substrate having an opening, a light emitting element disposed on the substrate, an inorganic layer disposed between the substrate and the light emitting element and having a plurality of holes overlapping the opening, pads disposed between the inorganic layer and the light emitting element and each partially exposed through the holes; and a circuit board at least partially disposed in the opening, spaced apart from the pads and the light emitting element with the inorganic layer interposed between the circuit board, and the pads and the light emitting element, and electrically connected to the pads exposed through the holes.

### CROSS-REFERENCE TO RELATED APPLICATION(S)

This application claims priority to and the benefit of Korean Patent Application No. 10-2024-0066632 under 35 U.S.C. § 119, filed on May 22, 2024, in the Korean Intellectual Property Office, the entire contents of which are incorporated herein by reference.

### BACKGROUND

### 1. Technical Field

The disclosure relates to a display device. More particularly, the disclosure relates to a display device having reduced dead space in a display panel and a manufacturing method of the display device.

### 2. Description of the Related Art

Research and development on display devices are ongoing due to the growing interest in information display.

The position of a driving chip for driving pixels of the display device may be determined in various ways. For example, the driving chip may be disposed on a back surface of the display device. At this time, one possible location for the wires that electrically connect the driving chip to the configuration of the display device may be disposed outside the display device.

Meanwhile, pixels may not be disposed in the outer area, and the outer area may be a dead space where light is not visible. It may be desirable for the area of dead space to be sufficiently reduced so that the display quality of the display device is improved.

### SUMMARY

The disclosure is to provide a display device where the area of the dead space is reduced.

The disclosure is to provide a manufacturing method of the display device.

The object of the disclosure is not limited to the aforesaid, but other objects not described herein will be clearly understood by those skilled in the art from descriptions below.

A display device according to embodiments of the disclosure includes a substrate having an opening, a light emitting element disposed on the substrate, an inorganic layer disposed between the substrate and the light emitting element and having a plurality of holes overlapping the opening in a thickness direction, pads disposed between the inorganic layer and the light emitting element and partially exposed through the holes respectively; and a circuit board at least partially disposed in the opening, spaced apart from the pads and the light emitting element with the inorganic layer interposed between the circuit board, and the pads and the light emitting element, and electrically connected to the pads exposed through the holes.

The display device may further include a conductive ink layer in direct contact with each of the pads and the circuit board.

The display device may further include a protective resin layer covering the conductive ink layer.

The display device may further include signal lines electrically connecting the pads and the light emitting element.

The display device may further include an insulating layer disposed on the inorganic layer and the pads and entirely covering upper surfaces of the pads.

The inorganic layer may include a first inorganic layer contacting an upper surface of the substrate and a second inorganic layer disposed on the first inorganic layer.

The first inorganic layer may have a plurality of first holes, the second inorganic layer may have a plurality of second holes overlapping the plurality of first holes respectively in the thickness direction, and the first holes and the second holes that overlap each other may constitute the holes respectively.

A planar size of each of the first holes may be smaller than a planar size of each of the second holes.

The pads may include first conductive layers contacting an upper surface of the inorganic layer and partially exposed through the holes respectively and second conductive layers respectively disposed on the first conductive layers and respectively overlapping the first conductive layers.

The pads may include first conductive layers contacting an upper surface of the inorganic layer and including sub-holes overlapping the holes respectively and second conductive layers respectively disposed on the first conductive layers and partially exposed through the holes and the sub-holes respectively.

A manufacturing method of a display device according to embodiments of the disclosure includes forming an inorganic layer disposed on a substrate, forming a plurality of holes in the inorganic layer, forming pads that respectively overlap the holes disposed on the inorganic layer, forming a light emitting element on the inorganic layer, forming an opening overlapping the holes in the substrate, and providing a circuit board that is at least partially disposed in the opening, is spaced apart from the pads and the light emitting element with the inorganic layer interposed between the circuit board, and the pads and the light emitting element, and is electrically connected to the pads exposed through the holes.

The method may further include forming a conductive ink layer which is in direct contact with each of the pads and the circuit board.

The method may further include forming a protective resin layer to cover the conductive ink layer.

The method further includes forming signal lines before forming the light emitting element, wherein the signal lines may connect the pads and the light emitting element.

The method may further include forming an insulating layer disposed on the inorganic layer and the pads to entirely cover upper surfaces of the pads.

The inorganic layer may include a first inorganic layer and a second inorganic layer, and the forming the inorganic layer may include forming a first inorganic layer to contact an upper surface of the substrate, forming a plurality of first holes in the first inorganic layer, forming a second inorganic layer on the first inorganic layer, and forming a plurality of second holes overlapping the first holes respectively in the second inorganic layer.

The first holes and the second holes, which overlap each other, may form the holes in a thickness direction, respectively.

A planar size of each of the first holes may be smaller than a planar size of each of the second holes.

The pads may include first conductive layers and second conductive layers, and the forming the pads may include forming a first preliminary conductive layer overlapping the holes on an upper surface of the inorganic layer, patterning the first preliminary conductive layer to form first conductive layers overlapping the holes respectively, forming a second preliminary conductive layer on the first conductive layers, and patterning the second preliminary conductive layer to form second conductive layers overlapping the first conductive layers respectively.

The pads may include first conductive layers and second conductive layers, and the forming the pads includes forming a first preliminary conductive layer overlapping the holes on an upper surface of the inorganic layer, patterning the first preliminary conductive layer to form the first conductive layers overlapping the holes respectively and sub-holes overlapping the holes respectively in the first conductive layers, forming a second preliminary conductive layer on the first conductive layers, and patterning the second preliminary conductive layer to form second conductive layers overlapping the sub-holes respectively.

Specific details of other embodiments are included in specification and drawings.

According to the above-described embodiment, an opening may be formed in the substrate, and the circuit board may be electrically connected to pads toward a bottom direction of the substrate through the opening. Accordingly, since the circuit board does not need to be bent, the area of dead space can be reduced. Additionally, since no separate process or mask is added to form pads electrically connected to the circuit board, manufacturing process costs can be reduced and manufacturing process efficiency can be improved.

Effects according to embodiments are not limited by contents above, and more various effects are included in the present specification.

### BRIEF DESCRIPTION OF THE DRAWINGS

FIG. 1 is a schematic block diagram showing an embodiment of a display device.

FIG. 2 is a schematic block diagram showing an embodiment of one of sub-pixels of FIG. 1.

FIG. 3 is a schematic plan view showing an embodiment of a display device of FIG. 1.

FIG. 4 is an enlarged schematic plan view of area A of FIG. 3.

FIG. 5 is a schematic cross-sectional view taken along line I-I′ of FIG. 4.

FIG. 6 is a schematic cross-sectional view taken along line II-II′ of FIG. 4.

FIG. 7 is a schematic cross-sectional view taken along line III-III′ of FIG. 4.

FIG. 8 is a schematic cross-sectional view showing a first embodiment of a display device.

FIG. 9 is a schematic cross-sectional view showing a second embodiment of a display device.

FIG. 10 is a schematic cross-sectional view showing a third embodiment of a display device.

FIG. 11 is a schematic cross-sectional view showing a fourth embodiment of a display device.

FIG. 12 is a schematic cross-sectional view showing a fifth embodiment of a display device.

FIG. 13 is a schematic cross-sectional view showing a sixth embodiment of a display device.

FIG. 14 is a schematic cross-sectional view showing a seventh embodiment of a display device.

FIG. 15 is a schematic cross-sectional view showing the eighth embodiment of a display device.

FIG. 16 is a schematic cross-sectional view showing the ninth embodiment of a display device.

FIG. 17 is a schematic cross-sectional view showing the tenth embodiment of a display device.

FIG. 18 is a schematic cross-sectional view showing the eleventh embodiment of a display device.

FIGS. 19 to 29 are schematic drawings showing a manufacturing method of a display device according to an embodiment of the disclosure.

FIGS. 30 to 36 are schematic drawings showing a first embodiment of a manufacturing method of a display device.

FIGS. 37 to 39 are schematic drawings showing a second embodiment of a manufacturing method of a display device.

FIGS. 40 to 46 are schematic drawings showing a third embodiment of a manufacturing method of a display device.

FIGS. 47 to 51 are schematic drawings showing a fourth embodiment of a manufacturing method of a display device.

FIGS. 52 to 54 are schematic drawings showing a fifth embodiment of a manufacturing method of a display device.

FIGS. 55 to 58 are schematic drawings showing a sixth embodiment of a manufacturing method of a display device.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

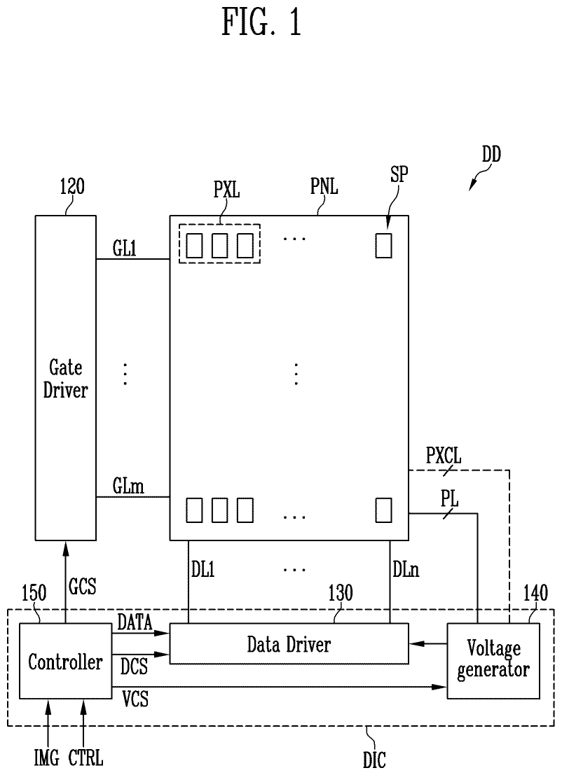

FIG. 1 is a schematic block diagram showing an embodiment of a display device.

Referring to FIG. 1, a display device DD may include a display panel PNL, a gate driver 120, a data driver 130, a voltage generator 140, and a controller 150.

The display panel PNL includes sub-pixels SP. The sub-pixels SP may be electrically connected to the gate driver 120 through the first to m-th gate lines GL1 to GLm. The sub-pixels SP may be electrically connected to the data driver 130 through the first to n-th data lines DL1 to DLn.

The sub-pixels SP may generate light of two or more colors. For example, each of the sub-pixels SP may generate light such as red, green, blue, cyan, magenta, yellow, etc.

Two or more sub-pixels among the sub-pixels SP may constitute one pixel PXL. For example, the pixel PXL may include three sub-pixels SP as shown in FIG. 1. The pixel PXL may emit light of various colors and various brightnesses depending on the combination of light emitted from the sub-pixels SP included in the pixel.

The gate driver 120 may be electrically connected to the sub-pixels SP arranged in the row direction through the first to m-th gate lines GL1 to GLm. The gate driver 120 may output gate signals to the first to m-th gate lines GL1 to GLm in response to a gate control signal GCS. The gate control signal GCS may include a start signal indicating the start of each frame, a horizontal synchronization signal, etc.

The gate driver 120 may be disposed on one side of the display panel PNL. However, the embodiments are not limited thereto. For example, the gate driver 120 may be divided into two or more drivers separated physically and/or logically, and such drivers may be disposed on a side of the display panel PNL and on another side of the display panel PNL. The gate driver 120 may be disposed around the display panel PNL in various shapes according to the embodiments.

The data driver 130 may be electrically connected to the sub-pixels SP arranged in a column direction through the first to n-th data lines DL1 to DLn. The data driver 130 may receive image data DATA and data control signal DCS from the controller 150. The data driver 130 may operate in response to the data control signal DCS. The data control signal DCS may include a source start signal, a source shift clock, a source output enable signal, etc.

The data driver 130 may receive voltages from the voltage generator 140. The data driver 130 may apply data signals having grayscale voltages corresponding to the image data DATA to the first to n-th data lines DL1 to DLn using the received voltages. When a gate signal is applied to each of the first to m-th gate lines GL1 to GLm, data signals corresponding to the image data DATA may be applied to the data lines DL1 to DLn. Accordingly, the sub-pixels SP may generate light corresponding to data signals, and the display panel PNL may display an image (or images).

The gate driver 120 and data driver 130 may include complementary metal-oxide semiconductor (CMOS) circuit elements.

The voltage generator 140 may operate in response to a voltage control signal VCS from controller 150. The voltage generator 140 may generate multiple voltages and provide the generated voltages to components of the display device DD, such as the gate driver 120, the data driver 130, and the controller 150. The voltage generator 140 may generate multiple voltages by receiving an input voltage from outside the display device DD and regulating the received voltage.

The voltage generator 140 may generate a first power voltage and a second power voltage. The generated first and second power voltages may be provided to the sub-pixels SP through the power lines PL. In another embodiment, at least one of the first and second power voltages may be provided from outside the display device DD.

The voltage generator 140 may provide various voltages and/or signals. For example, the voltage generator 140 may provide one or more initialization voltages applied to the sub-pixels SP. For example, during a sensing operation to sense electrical characteristics of the transistors and/or light emitting elements of the sub-pixels SP, a selected reference voltage may be applied to the first to n-th data lines DL1 to DLn, and the voltage generator 140 may generate the reference voltage and transmit it to the data driver 130. For example, during a display operation to display an image (or images) on the display panel PNL, common pixel control signals may be applied to the sub-pixels SP, and the voltage generator 140 may generate the pixel control signals. The voltage generator 140 may provide pixel control signals to the sub-pixels SP through the pixel control lines PXCL. In FIG. 1, the pixel control lines PXCL are shown as electrically connected between the voltage generator 140 and the display panel PNL, but the embodiments are not limited thereto. For example, the pixel control lines PXCL may be electrically connected between the gate driver 120 and the display panel PNL. Pixel control signals may be transmitted from the voltage generator 140 to the pixel control lines PXCL through the gate driver 120.

The controller 150 may control various operations of the display device DD. The controller 150 may receive input image data IMG and a corresponding control signal CTRL from the outside. The controller 150 may provide a gate control signal GCS, a data control signal DCS, and a voltage control signal VCS in response to the control signal CTRL.

The controller 150 may convert the input image data IMG to suit the display device DD or the display panel PNL and output image data DATA. The controller 150 may arrange the input image data IMG to suit the sub-pixels SP in units of rows and output image data DATA.

Two or more components of the data driver 130, voltage generator 140, and controller 150 may be mounted on one integrated circuit. As shown in FIG. 1, the data driver 130, voltage generator 140, and controller 150 may be included in a driver integrated circuit DIC. The data driver 130, voltage generator 140, and controller 150 may be functionally separate components in one driver integrated circuit DIC. In another embodiment, at least one of the data driver 130, the voltage generator 140, and the controller 150 may be provided as a separate component from the driver integrated circuit DIC.

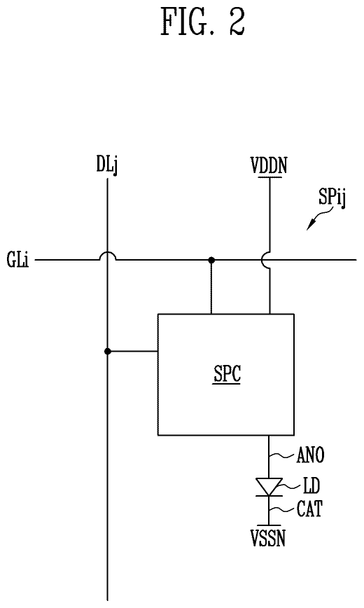

FIG. 2 is a schematic block diagram showing an embodiment of one of sub-pixels of FIG. 1. In FIG. 2, a sub-pixel SPij arranged in the i-th row (i is an integer greater than or equal to 1 and less than or equal to m) and the j-th column (j is an integer greater than or equal to 1 and less than or equal to n) among the sub-pixels SP of FIG. 1, may be shown as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL in FIG. 1 and receive the first power voltage. The second power voltage node VSSN may be electrically connected to another one of the power lines PL in FIG. 1 and receive the second power voltage. The first power voltage may have a higher voltage level than the second power voltage.

The light emitting element LD may be electrically connected between an anode electrode ANO and a cathode electrode CAT. The anode electrode ANO may be electrically connected to the first power voltage node VDDN through the sub-pixel circuit SPC. For example, the anode electrode ANO may be electrically connected to the first power voltage node VDDN through one or more transistors included in the sub-pixel circuit SPC. The cathode electrode CAT may be electrically connected to the second power voltage node VSSN. The light emitting element LD may emit light depending on the current flowing from the anode electrode ANO to the cathode electrode CAT.

The sub-pixel circuit SPC may be electrically connected to the i-th gate line GLi among the first to m-th gate lines GL1 to GLm of FIG. 1 and the j-th data line DLj among the first to n-th data lines DL1 to DLn of FIG. 1. In response to the gate signal received through the i-th gate line GLi, the sub-pixel circuit SPC may control the light emitting element LD to emit light depending on the data signal received through the j-th data line DLj. The sub-pixel circuit SPC may be further electrically connected to the pixel control lines PXC of FIG. 1. The sub-pixel circuit SPC may control the light emitting element LD in further response to pixel control signals received through the pixel control lines PXCL.

The sub-pixel circuit SPC may include circuit elements, such as transistors and one or more capacitors.

The transistors of the sub-pixel circuit SPC may include P-type transistors and/or N-type transistors. The transistors of the sub-pixel circuit SPC may include a metal oxide silicon field effect transistor (MOSFET). The transistors of the sub-pixel circuit SPC may include an amorphous silicon semiconductor, a monocrystalline silicon semiconductor, a polycrystalline silicon semiconductor, an oxide semiconductor, etc.

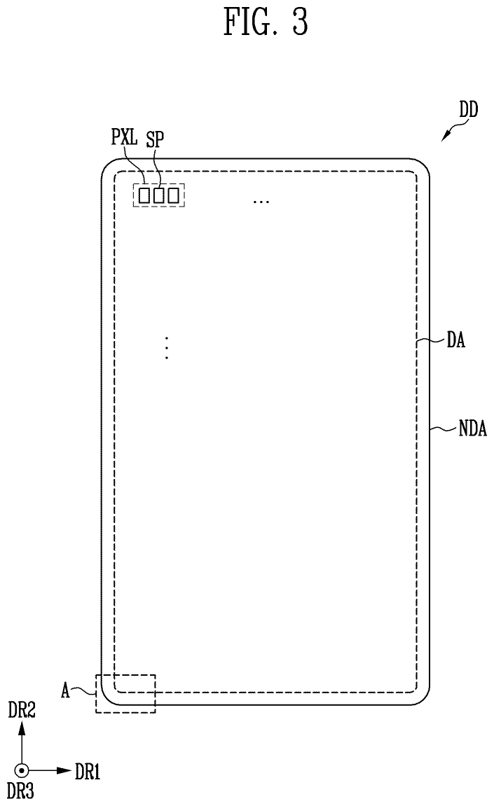

FIG. 3 is a schematic plan view showing an embodiment of a display device of FIG. 1.

Referring to FIG. 3, the display device DD may include a display area DA and a non-display area NDA. The display device DD may display an image (or images) through the display area DA. The non-display area NDA may be disposed around the display area DA. For example, the non-display area NDA may be disposed outside of the display area DA.

The display device DD may include multiple pixels PXL in the display area DA. The plurality of pixels PXL may be arranged in the first direction DR1 and the second direction DR2 that intersects the first direction DR1. For example, the plurality of pixels PXL may be arranged in a matrix form in the first direction DR1 and the second direction DR2. In another example, multiple pixels PXL may be arranged in a zigzag shape in the first direction DR1 and the second direction DR2. The arrangement of the plurality of pixels PXL may vary according to embodiments. The first direction DR1 may be a row direction, and the second direction DR2 may be a column direction. A third direction DR3 may be defined orthogonal to the first direction DR1 and the second direction DR2. Hereinafter, among surfaces of one layer, a surface disposed in the third direction DR3 will be described as an upper surface, and a surface disposed in the opposite direction to the third direction DR3 will be described as a lower surface.

One pixel PXL may include two or more sub-pixels SP. Hereinafter, the pixel PXL is shown as including three sub-pixels SP, but embodiments are not limited thereto. For example, the pixel PXL may include two sub-pixels. Hereinafter, for convenience of description, it is assumed that the pixel PXL includes first to third sub-pixels.

A display panel capable of self-emitting light, such as a light emitting diode display panel (LED display panel) using micro-scale or nano-scale light emitting diodes as a light emitting element, an organic light emitting display panel (OLED) using organic light emitting diodes as a light emitting element, a hybrid display panel using micro-scale or nano-scale light emitting diodes and organic light emitting diodes as light emitting elements, and the like, may be used as a display device DD.

Components for controlling multiple pixels PXL may be disposed in the non-display area NDA. The lines electrically connected to multiple pixels PXL, for example, the first to m-th gate lines GL1 to GLm, the first to n-th data lines DL1 to DLn, power lines PL, and pixel control lines PXCL of FIG. 1 may be disposed in the non-display area NDA.

At least one of the gate driver 120, data driver 130, voltage generator 140, and controller 150 of FIG. 1 may be disposed in the non-display area NDA of the display device DD. The gate driver 120 may be disposed in the non-display area NDA. The data driver 130, the voltage generator 140, and the controller 150 may be implemented as the driver integrated circuit DIC separated from the display device DD of FIG. 1, and the driver integrated circuit DIC may be electrically connected to lines arranged in the non-display area NDA. In another embodiment, the gate driver 120 may be implemented together with the data driver 130, the voltage generator 140, and the controller 150 as an integrated circuit separated from the display device DD.

The display area DA may have various shapes. The display area DA may have a closed loop shape including straight and/or curved sides. For example, the display area DA may have shapes such as a polygon, circle, semicircle, or ellipse.

The display device DD may have a flat display surface. In another embodiment, the display device DD may have a display surface that is at least partially round. The display device DD may be bendable, foldable, or rollable. The display device DD and/or the substrate of the display device DD may include materials having flexible properties.

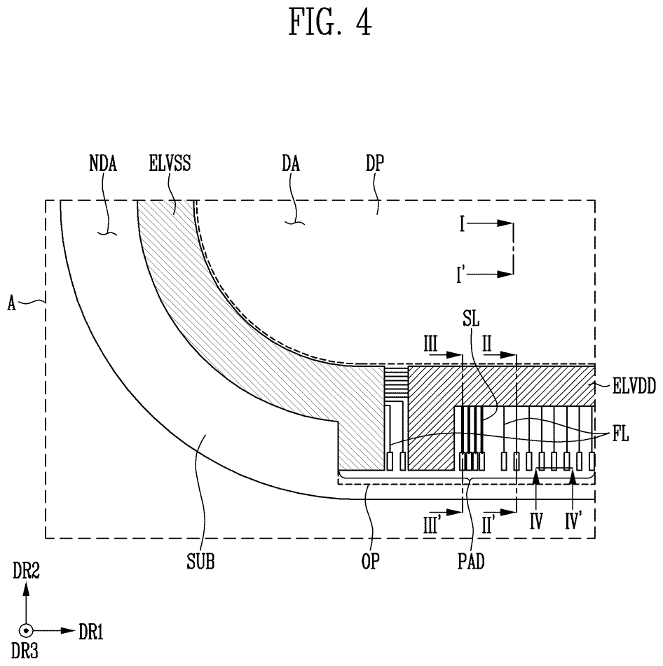

FIG. 4 is an enlarged schematic plan view of area A of FIG. 3.

Referring to FIG. 4, a display layer DP corresponding to multiple pixels PXL may be disposed in the display area DA on the substrate SUB. Lines electrically connected to the display layer DP and pads PAD electrically connected to the lines may be disposed in the non-display area NDA on the substrate SUB.

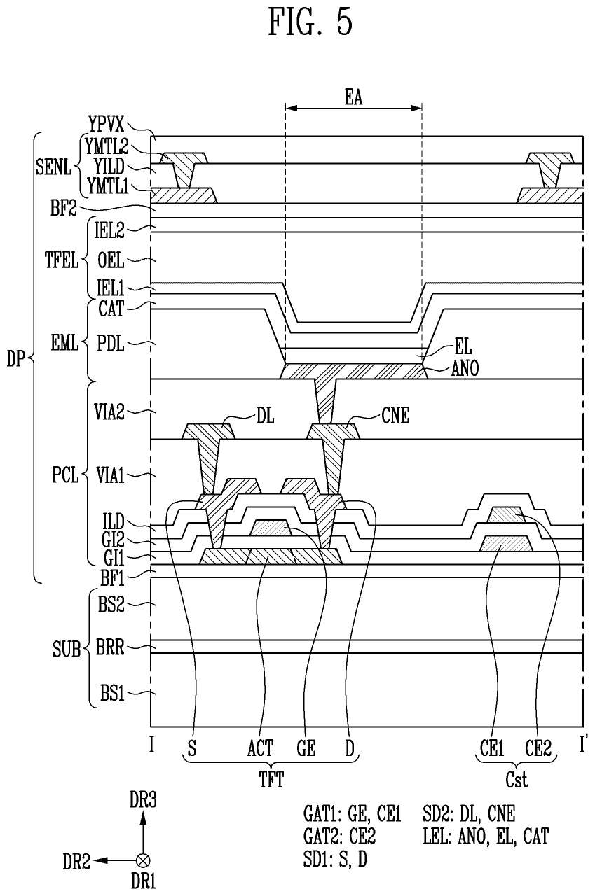

For example, in the non-display area NDA, a first power voltage supply line ELVDD which are included in the power lines PL of FIG. 1 and supply the first power voltage VDDN of FIG. 2, a second power voltage supply line ELVSS that supplies the second power voltage VSSN, signal lines FL electrically connected to each of the first to m-th gate lines GL1 to GLm and the first to n-th data lines DL1 to DLn of FIG. 1, sensing lines SL electrically connected to the sensing layer (e.g., sensing layer SENL in FIG. 5) included in the display layer DP, and pads PAD electrically connected to each of lines (e.g., first power voltage supply line ELVDD, second power voltage supply line ELVSS, signal lines FL, and sensing lines SL) disposed in the non-display area NDA, may be disposed.

However, the embodiments are not limited thereto. For example, one of the lines and pads PAD may be disposed between the substrate SUB overlapping the display area DA and the display layer DP in the display area DA on the substrate SUB, other lines may be disposed in the non-display area NDA. For another example, in the display area DA on the substrate SUB, all of the lines and pads PAD may be disposed between the substrate SUB and the display layer DP. As such, the arrangement relationship of the display layer DP, the lines, and the pads PAD may be selected in one of various ways. Hereinafter, for convenience of description, it will be described that the display layer DP is disposed in the display area DA, and the lines and pads PAD are disposed in the non-display area NDA.

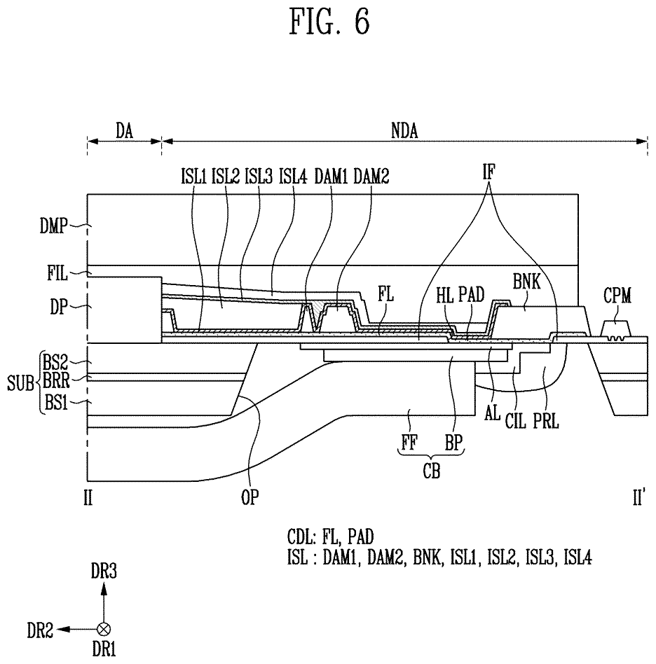

The substrate SUB may have an opening OP that overlaps the pads PAD and some of the lines. lower surfaces of the pads PAD may be exposed through the opening OP, and the pads PAD and a circuit board (e.g., circuit board CB in FIG. 6) may be electrically connected through the opening OP.

FIG. 5 is a schematic cross-sectional view taken along line I-I′ of FIG. 4.

For convenience of illustration, only the substrate SUB and the display layer DP on the substrate SUB are shown in FIG. 5.

Referring to FIG. 5, the display layer DP may include a first buffer layer BF1, a circuit element layer PCL, a light emitting element layer EML, a thin film encapsulation layer TFEL, and a sensing layer SENL disposed on the substrate SUB of FIG. 4. The circuit element layer PCL may include thin film transistors TFT, a first gate insulating layer GI1, a first gate conductive layer GAT1, a second gate insulating layer GI2, a second gate conductive layer GAT2, an interlayer insulating layer ILD, a first metal conductive layer SD1, a second metal conductive layer SD2, a first via insulating layer VIA1, and a second via insulating layer VIA2.

The substrate SUB may function to support various components disposed on the substrate SUB. The substrate SUB may be made of an insulating material such as glass or resin.

The substrate SUB may be made of a flexible material that can be bent or folded, and may have a single-layer structure or a multi-layer structure. The substrate SUB may include a polyimide substrate. For example, the substrate SUB may include a first base substrate BS1 including polyimide, a barrier layer BRR disposed on the first base substrate BS1 and including an inorganic material, and a second base substrate BS2 disposed on the barrier layer BRR and including polyimide.

However, the disclosure is not limited thereto, and for another example, the substrate SUB may include a glass substrate. As another example, the substrate SUB may include a silicon wafer substrate formed using a semiconductor process.

The first buffer layer BF1 may be disposed on the substrate SUB. For example, the first buffer layer BF1 may be disposed on the second base substrate BS2. The first buffer layer BF1 may be disposed on the upper surface of the substrate (SUB) to protect the thin film transistors TFT and the light emitting layer EL of the light emitting element layer EML from moisture penetrating through the substrate SUB, which is vulnerable to moisture permeation.

The first buffer layer BF1 may be an inorganic layer. The first buffer layer BF1 may be made of multiple inorganic layers alternately stacked. For example, the first buffer layer BF1 may be made of a multilayer in which one or more inorganic layers of a silicon nitride layer, a silicon oxy nitride layer, a silicon oxide layer, a titanium oxide layer, and an aluminum oxide layer are alternately stacked. In some embodiments, the first buffer layer BF1 may be omitted.

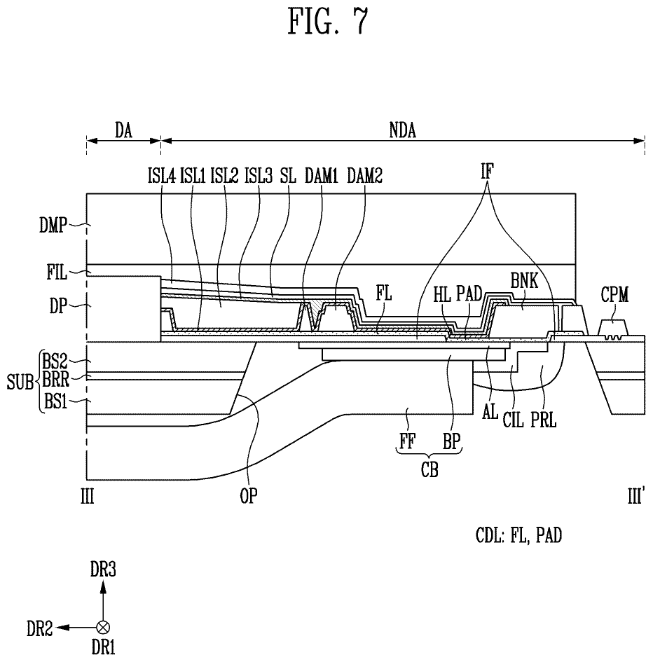

The circuit element layer PCL including thin film transistors TFT may be disposed on the first buffer layer BF1. The thin film transistor TFT may include an active layer ACT, a gate electrode GE, a source electrode S, and a drain electrode D. In FIG. 7, it is illustrated that the gate electrode (GE) of the thin film transistor TFT is arranged in a top gate type disposed on the active layer (ACT), but the disclosure is not limited thereto. For example, in other embodiments, the thin film transistors TFT may be arranged in a bottom gate type, in which the gate electrode GE is disposed under the active layer ACT or a double gate type, in which the gate electrode GE is disposed both on and under the active layer ACT.

The active layer ACT may be disposed on the first buffer layer BF1. The active layer ACT may include polycrystalline silicon, single crystalline silicon, low-temperature polycrystalline silicon, amorphous silicon, or an oxide semiconductor. For example, oxide semiconductors may include binary compounds (ABx), ternary compounds (ABxCy), and a four-component compound (ABxCyDz) containing indium, zinc, gallium, tin, titanium, aluminum, hafnium (Hf), zirconium (Zr), magnesium (Mg), etc. For example, the active layer ACT may include ITZO (oxide containing indium, tin, and titanium) or IGZO (oxide containing indium, gallium, and tin).

The first gate insulating layer GI1 may be disposed on the active layer ACT. The first gate insulating layer GI1 and the active layer ACT may have substantially equal thickness along a profile of the active layer ACT. The first gate insulating layer GI1 may be an inorganic layer. For example, the first gate insulating layer GI1 may be made of a silicon nitride layer, a silicon oxy nitride layer, a silicon oxide layer, a titanium oxide layer, or an aluminum oxide layer. FIG. 5 illustrates that the first gate insulating layer GI1 is disposed in addition to an area overlapping the gate electrode GE, but the disclosure is not limited thereto. For example, in other embodiments, the first gate insulating layer GI1 may be disposed only in an area overlapping the gate electrode GE.

The first gate conductive layer GAT1 may be disposed on the first gate insulating layer GI1. The first gate conductive layer GAT1 may include a gate electrode GE of the thin film transistor TFT, a first electrode CE1 of the storage capacitor Cst, and a scan line. The gate electrode GE may be disposed on the first gate insulting layer GI1 and overlap the active layer ACT in the third direction DR3. The first gate insulating layer GI1 may be disposed between the active layer ACT and the gate electrode GE.

The first gate conductive layer GAT1 may be made of a single layer or multiple layers made of any one of molybdenum (Mo), aluminum (Al), chromium (Cr), gold (Au), titanium (Ti), nickel (Ni), neodymium (Nd), and copper (Cu), or an alloy thereof.

The second gate insulating layer GI2 may be disposed on the first gate conductive layer GAT1. The second gate insulating layer GI2 may be disposed on the first gate insulating layer GI1 on which the first gate conductive layer GAT1 is disposed and may cover the first gate conductive layer GAT1. The second gate insulating layer GI2 and the first gate conductive layer GAT1 may have substantially equal thickness along the profile of the first gate conductive layer GAT1. The second gate insulating layer GI2 may be an inorganic layer. For example, the second gate insulating layer GI2 may include the same material as the first gate insulating layer GI1. However, the embodiments are not limited thereto.

The second gate conductive layer GAT2 may be disposed on the second gate insulating layer GI2. The second gate conductive layer GAT2 may include a second electrode CE2 of the storage capacitor Cst. For example, the second electrode CE2 may form a storage capacitor Cst with the first electrode CE1. The second electrode CE2 may overlap the first electrode CE1 in the third direction DR3 (e.g., thickness direction).

The interlayer insulating layer ILD may be disposed on the second gate insulating layer GI2 on which the second gate conductive layer GAT2 is disposed. The interlayer dielectric layer ILD may be an inorganic layer. For example, the interlayer insulating layer ILD may be made of a silicon nitride layer, a silicon oxy nitride layer, a silicon oxide layer, a titanium oxide layer, or an aluminum oxide layer.

The first metal conductive layer SD1 may be disposed on the interlayer insulating layer ILD. The first metal conductive layer SD1 may be made of a single layer or multiple layers made of any one of molybdenum (Mo), aluminum (Al), chromium (Cr), gold (Au), titanium (Ti), nickel (Ni), neodymium (Nd), and copper (Cu), or an alloy thereof. For example, the first metal conductive layer SD1 may have a multi-layer structure. For example, the first metal conductive layer SD1 may have a two-layer structure of Ti/Al or a three-layer structure of Ti/Al/Ti.

The first metal conductive layer SD1 may include the source electrode S and the drain electrode D of the thin film transistor TFT. Each of the source electrode S and the drain electrode D may be electrically connected to the active layer ACT through a contact hole penetrating the first gate insulating layer GI1, the second gate insulating layer GI2, and the interlayer insulating layer ILD in the third direction.

The first via insulating layer VIA1 may partially insulate the first metal conductive layer SD1 and the second metal conductive layer SD2, which will be described later, and may serve to flatten a step caused by the element of the thin film transistor TFT. The first via insulating layer VIA1 may be disposed on the interlayer insulating layer ILD on which the first metal conductive layer SD1 is disposed. The first via insulating layer VIA1 may be an organic layer. The first via insulating layer VIA1 may be made of an organic insulating material such as acrylic resin, polyimide resin, or polyamide resin. For example, the first via insulating layer VIA1 may include at least one substance of acryl resin, epoxy resin, phenolic resin, polyamide resin, or polyimide resin.

The second metal conductive layer SD2 may be disposed on the first via insulating layer VIA1. The second metal conductive layer SD2 may include metal. The second metal conductive layer SD2 may include at least one metals selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). For example, the second metal conductive layer SD2 may have a multi-layer structure. For example, the second metal conductive layer SD2 may have a two-layer structure of Ti/Al or a three-layer structure of Ti/Al/Ti.

The second metal conductive layer SD2 may include a connection electrode CNE, a data line DL, and an initialization voltage line, and the like that are electrically connected to the source electrode S or drain electrode D of the thin film transistor TFT. For example, the connection electrode CNE may be electrically connected to the drain electrode D, as shown in FIG. 5. The connection electrode CNE may be electrically connected to the drain electrode D through a contact hole penetrating the first via insulating layer VIA1. The data line DL may be electrically connected to the source electrode S. The data line DL may be electrically connected to source electrode S through a contact hole penetrating the first via insulating layer VIA1.

The second via insulating layer VIA2 may be disposed on the first via insulating layer VIA1 on which the second metal conductive layer SD2 is disposed. The second via insulating layer VIA2 may be an organic layer. The second via insulating layer VIA2 may include at least one material selected from acrylic resin, polyimide resin, and polyamide resin.

The light emitting element layer EML may be disposed on the circuit element layer PCL. The light emitting element layer EML may include light emitting elements LEL and a pixel definition layer PDL.

Each of the light emitting elements LEL may include an anode electrode ANO, a light emitting layer EL, and a cathode electrode CAT, and the light emitting elements LEL and the pixel definition layer PDL may be formed on the second via insulating layer VIA2.

The anode electrode ANO of the light emitting element LEL may be electrically connected to the connection electrode CNE through a contact hole penetrating the second via insulating layer VIA2 and may be electrically connected to the drain electrode D of the thin film transistor TFT.

In a top emission structure, which emits light in the direction of the cathode electrode CAT based on the light emitting layer EL, the anode electrode ANO may be formed of a highly reflective metal material such as a stacked structure of aluminum and titanium (Ti/Al/Ti), a stacked structure of aluminum and ITO (ITO/AI/ITO), APC alloy, and a stacked structure of APC alloy and ITO (ITO/APC/ITO). The APC alloy may be an alloy of silver (Ag), palladium (Pd), and copper (Cu). In another example, the anode electrode ANO may be made of a single layer of molybdenum (Mo), titanium (Ti), copper (Cu), and aluminum (Al).

In a bottom structure, which emits light in the direction of the anode electrode ANO based on the light emitting layer EL, the anode electrode ANO may be made of a transparent conductive material (TCO) such as ITO or IZO that can transmit light or semi-transmissive conductive material such as magnesium (Mg), silver (Ag), or an alloy of magnesium (Mg) and silver (Ag).

The pixel definition layer PDL may define a light emitting area EA of each of the sub-pixels SP. The pixel definition layer may be disposed to partition the anode electrode ANO on the second via insulating layer VIA2. The pixel definition layer PDL may be disposed to cover an edge of the anode electrode ANO. The pixel definition layer PDL may be an organic layer. For example, the pixel definition layer PDL may be made of acryl resin, epoxy resin, phenolic resin, polyamide resin, polyimide resin, etc.

The light emitting area EA may represent areas that the anode electrode ANO, the light emitting layer EL, and the cathode electrode CAT are sequentially stacked in the third direction DR3 so that holes from the anode electrode ANO and electrons from the cathode electrode CAT are combined with each other in the light emitting layer EL and emit light.

The light emitting layer EL may be disposed on the anode electrode ANO and the pixel definition layer PDL. The light emitting layer EL may contain an organic material and emit light of a selected color. For example, the light emitting layer EL may include a hole transporting layer, an organic material layer, and an electron transporting layer. The light emitting layer EL of the light emitting area EA may emit light with one of red, green, and blue colors.

The cathode electrode CAT may be disposed on the light emitting layer EL. The cathode electrode CAT may be disposed to cover the light emitting layer EL. The cathode electrode CAT may be a common layer commonly formed in the pixels.

In the top emission structure, the cathode electrode CAT may be made of a transparent conductive material (TCO) such as ITO or IZO that can transmit light, or a semi-transmissive conductive material such as magnesium (Mg), silver (Ag), or an alloy of magnesium (Mg) and silver (Ag).

In the bottom emission structure, the cathode electrode CAT may be made of a highly reflective metal material such as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The APC alloy may be an alloy of silver (Ag), palladium (Pd), and copper (Cu). However, the disclosure is not limited thereto, and in another embodiment, the cathode electrode CAT may be made of a single layer of molybdenum (Mo), titanium (Ti), copper (Cu), aluminum (Al), or ITO.

The thin film encapsulation layer TFEL may be disposed on the light emitting element layer EML. The thin film encapsulation layer TFEL may be disposed on the cathode electrode CAT. The thin film encapsulation layer TFEL may include at least one inorganic layer to prevent oxygen or moisture from penetrating into the light emitting layer EL and the cathode electrode CAT. The thin film encapsulation layer TFEL may include at least one organic layer to protect the light emitting element layer EML from foreign substances such as dust.

For example, the thin film encapsulation layer TFEL may include a first inorganic encapsulation layer IEL1 disposed on the cathode electrode CAT, an organic encapsulation layer OEL disposed on the first inorganic encapsulation layer IEL1, and a second inorganic encapsulation layer IEL2 disposed on the organic encapsulation layer OEL. Each of the first inorganic encapsulation layer IEL1 and the second inorganic encapsulation layer IEL2 may be made of a silicon nitride layer, a silicon oxy nitride layer, a silicon oxide layer, a titanium oxide layer, or an aluminum oxide layer, but is not limited thereto. The organic encapsulation layer OEL may be made of acrylic resin, epoxy resin, phenolic resin, polyamide resin, polyimide resin, etc. but is not limited thereto.

The sensing layer SENL may be disposed on the thin film encapsulation layer TFEL. The sensing layer SENL may include first sensing electrodes YMTL1, a first sensing insulating layer YILD, a second sensing electrode YMTL2, and a second sensing insulating layer YPVX.

The second buffer layer BF2 may be disposed on the thin film encapsulation layer TFEL. The second buffer layer BF2 may be made of a multilayer in which at least one inorganic layer selected from the group consisting of a silicon nitride layer, a silicon oxy nitride layer, a silicon oxide layer, a titanium oxide layer, and an aluminum oxide layer are alternately stacked.

The first sensing electrodes YMTL1 may be disposed on the second buffer layer BF2. The first sensing electrodes YMTL1 may be made of a stacked structure of aluminum and titanium (Ti/Al/Ti), a stacked structure of aluminum and ITO (ITO/AI/ITO), an APC alloy, and a stacked structure of APC alloy and ITO (ITO/APC/ITO), but is not limited thereto. For another example, the first sensing electrodes YMTL1 may be made of a single layer of molybdenum (Mo), titanium (Ti), copper (Cu), aluminum (Al), or ITO.

The first sensing insulating layer YILD may be disposed on the second buffer layer BF2 where the first sensing electrodes YMTL1 are disposed. The first sensing insulating layer YILD may be made of an inorganic layer, for example, a silicon nitride layer, a silicon oxy nitride layer, a silicon oxide layer, a titanium oxide layer, or an aluminum oxide layer.

For example, the first sensing insulating layer YILD may be made of an organic layer such as acryl resin, epoxy resin, phenolic resin, polyamide resin, polyimide resin, etc.

The second sensing electrode YMTL2 may be disposed on the first sensing insulating layer YILD. The second sensing electrode YMTL2 may be made of a stacked structure of aluminum and titanium (Ti/Al/Ti), a stacked structure of aluminum and ITO (ITO/AI/ITO), an APC alloy, and a stacked structure of APC alloy and ITO (ITO/APC/ITO), but is not limited thereto. For example, the second sensing electrode YMTL2 may be made of a single layer of molybdenum (Mo), titanium (Ti), copper (Cu), aluminum (Al), or ITO.

The contact holes to respectively expose the first sensing electrodes YMTL1 through the first sensing insulating layer YILD, may be formed in the first sensing insulating layer YILD. The second sensing electrode YMTL2 may be electrically connected to the first sensing electrodes YMTL1 through the contact holes. Portions of the second sensing electrode YMTL2 shown in FIG. 5 may be electrically connected to each other on the first sensing insulating layer YILD. Accordingly, the first sensing electrodes YMTL1 disposed on the second buffer layer BF2 may be electrically connected to each other through the second sensing electrode YMTL2.

In FIG. 5, the first sensing electrodes YMTL1 are shown as being disposed between the thin film encapsulation layer TFEL and the first sensing insulating layer YILD, but the embodiments are not limited thereto. For example, the second sensing electrode YMTL2 may be disposed between the thin film encapsulation layer TFEL and the first sensing insulating layer YILD, and the first sensing electrodes YMTL1 may be disposed on the first sensing insulating layer YILD.

The second sensing insulating layer YPVX may be disposed on the second sensing electrode YMTL2. The second sensing insulating layer YPVX may serve to flatten the step caused by the second sensing electrode YMTL2. The second sensing insulating layer YPVX may be made of an organic layer such as acryl resin, epoxy resin, phenolic resin, polyamide resin, polyimide resin, etc.

FIG. 6 is a schematic cross-sectional view taken along line II-II′ of FIG. 4. FIG. 7 is a schematic cross-sectional view taken along line III-III′ of FIG. 4.

Referring to FIGS. 6 and 7, the display layer DP including the light emitting element LEL of FIG. 5 may be disposed in the display area DA on the substrate SUB. An inorganic layer IF, multiple insulating layers ISL1, ISL2, ISL3, and ISL4, dams DAM1 and DAM2, a bank BNK, and a crack prevention layer CPM a filling layer FIL, and a damping layer DMP may be disposed in the non-display area NDA on the substrate SUB.

The substrate SUB may have an opening OP that overlaps the non-display area NDA. However, embodiments according to the disclosure are not limited thereto, and the substrate SUB may have an opening OP that overlaps the display area DA. Hereinafter, for convenience of description, the substrate SUB will be described as having an opening OP that overlaps the non-display area NDA.

The circuit board CB may be at least partially disposed inside the opening OP. The circuit board CB may be electrically connected to the display layer DP through pads PAD, which will be described later, and the driver integrated circuit DIC of FIG. 1 may be mounted on the circuit board CB.

The circuit board CB may be spaced apart from the layers (e.g., the display layer DP, multiple insulating layers ISL1, ISL2, ISL3, and ISL4, the dams DAM1 and DAM2, the bank BNK, the crack prevention layer CPM, the filling layer FIL, and the damping layer DMP) on the substrate SUB with the inorganic layer IF interposed therebetween. For example, the layers on the substrate SUB may be disposed in the third direction DR3 based on the inorganic layer IF, and the circuit board CB may be disposed in opposite direction of the third direction DR3 based on the inorganic layer IF.

The inorganic layer IF may be disposed on the substrate SUB. A lower surface of the inorganic layer IF and an upper surface of the substrate SUB may contact each other.

The inorganic layer IF may extend from the inorganic layer of the display layer DP. The inorganic layer IF may be a single-layer or a multi-layer extended from at least one of the first buffer layer BF1, the first gate insulating layer GI1, the second gate insulating layer GI2, and the interlayer insulating layer ILD of the display layer DP.

The inorganic layer IF may have multiple holes HL that overlap the opening OP of the substrate SUB.

The conductive layer CDL may be disposed on the inorganic layer IF. The conductive layer CDL may have equal material to at least one of the first gate conductive layer GAT1, the second gate conductive layer GAT2, the first metal conductive layer SD1, and the second metal conductive layer SD2 of the display layer DP. For example, the conductive layer CDL may extend from the display layer DP. For example, the conductive layer CDL may have a single-layer structure or a multi-layer structure extending from at least one layer of the first gate conductive layer GAT1, the second gate conductive layer GAT2, the first metal conductive layer SD1, and the second metal conductive layer SD2 of the display layer DP. For example, the conductive layer CDL may have a single-layer structure extending from the first metal conductive layer SD1. However, embodiments of the disclosure are not limited thereto.

The conductive layer CDL may include the signal lines FL and the pads PAD of FIG. 4.

The signal lines FL may connect the display layer DP and the pads PAD. In FIG. 6, each of the signal lines FL and the pads PAD is shown to be composed of one layer and extend integrally, but the disclosure is not limited thereto and, for example, each of the signal lines FL and the pads PAD may be composed of different layers and may be electrically connected to each other through contact holes.

The pads PAD may be disposed on the inorganic layer IF and may overlap the holes HL of the inorganic layer IF, respectively. The pads PAD may be partially exposed toward the bottom direction of the inorganic layer IF through the holes HL respectively.

The crack prevention layer CPM may be disposed on the inorganic layer IF. The crack prevention layer CPM may be disposed in the non-display area NDA to prevent cracks from occurring when cutting during the process of forming the display device DD.

An insulating layer ISL may be disposed on the inorganic layer IF and the conductive layer CDL. The insulating layer ISL may be disposed on the pads PAD and may entirely cover the upper surfaces of the pads PAD. The insulating layer ISL may have a multilayer structure.

The insulating layer ISL may extend from the display layer DP or may include the same material as a portion of the display layer DP. For example, the insulating layer ISL may be a layer extending from at least one of the first via insulating layer VIA1, the second via insulating layer VIA2, the pixel definition layer PDL, the first inorganic encapsulation layer IEL1, the organic encapsulation layer OEL, the second inorganic encapsulation layer IEL2, the first sensing insulating layer YILD, and the second sensing insulating layer YPVX of the display layer DP.

The insulating layer ISL may include a first dam DAM1, a second dam DAM2, a bank BNK, a first insulating layer ISL1, a second insulating layer ISL2, a third insulating layer ISL3, and a fourth insulating layer ISL4.

The first dam DAM1, the second dam DAM2, and the bank BNK may be disposed in the non-display area NDA on the conductive layer CDL.

The first dam DAM1 may have a multi-layer structure. The first dam DAM1 may include equal material to at least one of the first via insulating layer VIA1, the second via insulating layer VIA2, and the pixel definition layer PDL of the display layer DP. The first dam DAM1 may cover a side surface of the second insulating layer ISL2 including organic materials, which will be described later, and may prevent the organic materials from overflowing.

The second dam DAM2 may be disposed in a direction away the display layer DP from the first dam DAM1. The second dam DAM2 may be arranged to surround an exterior of the first dam DAM1. The second dam DAM2 may have a multi-layer structure. The second dam DAM2 may include the same material as at least one of the first via insulating layer VIA1, the second via insulating layer VIA2, and the pixel definition layer PDL of the display layer DP.

The bank BNK may be spaced apart further from the display layer DP and the display area DA than the first dam DAM1 and the second dam DAM2 in the second direction DR2. For example, the bank BNK may overlap the pads PAD. However, embodiments according to the disclosure are not limited thereto. The bank BNK may have a multi-layer structure. The bank BNK may serve to support a mask for forming first to third insulating layers ISL1, ISL2, and ISL3, which will be described later. The bank BNK may include the same material as at least one of the first via insulating layer VIA1, the second via insulating layer VIA2, and the pixel definition layer PDL of the display layer DP.

The first insulating layer ISL1 may be disposed over the inorganic layer IF. The first insulating layer ISL1 may include an inorganic material. The first insulating layer ISL1 may include the same material as the first inorganic encapsulation layer IEL1 of the display layer DP, and may extend from the first inorganic encapsulation layer IEL1.

The second insulating layer ISL2 may be disposed on the first insulating layer ISL1. The second insulating layer ISL2 may include an organic material. The second insulating layer ISL2 may include the same material as the organic encapsulation layer OEL of the display layer DP and may extend from the organic encapsulation layer OEL.

The third insulating layer ISL3 may be disposed on the second insulating layer ISL2. The third insulating layer ISL3 may include an inorganic material. The third insulating layer ISL3 may include the same material as the second inorganic encapsulation layer IEL2 of the display layer DP, and may extend from the second inorganic encapsulation layer IEL2.

The fourth insulating layer ISL4 may be disposed on the third insulating layer ISL3. The fourth insulating layer ISL4 may include the same material as at least one of the first sensing insulating layer YILD and the second sensing insulating layer YPVX of the display layer DP, and may extend from at least one of the first sensing insulating layer YILD and the second sensing insulating layer YPVX.

The filling layer FIL may be entirely disposed on the display layer DP and the insulating layer ISL. The filling layer FIL may be a layer for filling a space between the damping layer DMP and the display layer DP and between the damping layer DMP and the insulating layer ISL. The filled layer FIL may include an organic material.

The damping layer DMP may be disposed on the filling layer FIL. The damping layer DMP may include a material that functions as a polarizer, but the disclosure is not limited thereto.

The circuit board CB may be at least partially disposed inside the opening OP. The circuit board CB may be disposed on the lower surface of the inorganic layer IF and the lower surfaces of the pads PAD.

The circuit board CB may contact the lower surfaces of the pads PAD exposed through the opening OP of the substrate SUB and the holes HL of the inorganic layer IF. The circuit board CB may be electrically connected to the lower surface of the inorganic layer IF and the lower surfaces of the pads PAD exposed through the holes HL through an adhesive layer AL.

The circuit board CB may include bumps BP contacting the adhesive layer AL and a flexible film FF electrically connected to the bumps BP. The bumps BP may contact the pads PAD through the adhesive layer AL.

The conductive ink layer CIL disposed on the lower surfaces of the pads PAD and contacting the bumps BP, may be disposed. The conductive ink layer CIL may directly contact the pads PAD and the bumps BP included in the circuit board CB and may connect the pads PAD and the bumps BP to each other. The pads PAD and the circuit board CB may be electrically connected to each other through the conductive ink layer CIL. Accordingly, the signal from the display layer DP may be transmitted to the circuit board CB along the pads PAD and the conductive ink layer CIL.

The conductive ink layer CIL may include metal. For example, the conductive ink layer CIL may include at least one of silver (Ag) and copper (Cu).

The protective resin layer PRL may be disposed on the conductive ink layer CIL. The protective resin layer PRL may include organic material. The protective resin layer PRL may cover the conductive ink layer CIL and may protect the conductive ink layer CIL. However, the disclosure is not limited thereto, and in another embodiment, the protective resin layer PRL may cover not only the conductive ink layer CIL but also a portion of the circuit board CB.

Since the circuit board CB is disposed on a side of the lower surface of the substrate SUB, the circuit board CB does not need to be bent so that an area of the dead space generated by bending the circuit board CB may be reduced. Since no additional layer is required, the structure of the display device may be simplified.

FIG. 7 is a schematic cross-sectional view taken along line III-III′ of FIG. 5.

Referring to FIG. 7, sensing lines SL may be further disposed between the third insulating layer ISL3 and the fourth insulating layer ISL4. The sensing lines SL may include equal material to at least one of the first sensing electrode YMTL1 and the second sensing electrode YMTL2 of the display layer DP. The sensing lines SL and the first sensing electrodes YMTL1 of FIG. 5 may be disposed in the same layer. The sensing lines SL and the second sensing electrode YMTL2 of FIG. 5 may be disposed in the same layer.

The sensing lines SL may be electrically connected to the display layer DP. The sensing lines SL may be electrically connected to the first sensing electrode YMTL1 and the second sensing electrode YMTL2 of the display layer DP. The sensing lines SL may transmit signals transmitted from the first sensing electrode YMTL1 and the second sensing electrode YMTL2.

The sensing lines SL may be electrically connected to the pads PAD through contact holes defined in the bank BNK, respectively. As the sensing lines SL are electrically connected to the pads PAD, a signal transmitted from the sensing layer SENL may be transmitted to the circuit board CB.

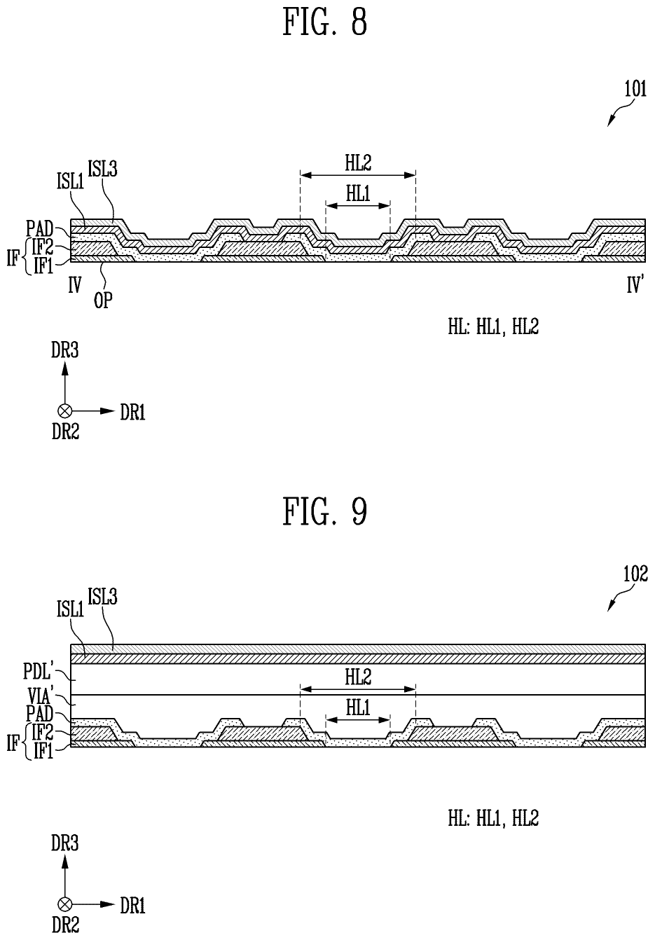

FIG. 8 is a schematic cross-sectional view showing a first embodiment 101 of a display device. For example, FIG. 8 is a schematic cross-sectional view taken along line IV-IV′ of FIG. 4. Hereinafter, for convenience of description, the circuit board CB may be omitted.

Referring to FIG. 8, the inorganic layer IF may include a first inorganic layer IF1 and a second inorganic layer IF2 disposed on the first inorganic layer IF1. Each of the first inorganic layer IF1 and the second inorganic layer IF2 may have a single-layer structure or a multi-layer structure.

The first inorganic layer IF1 may be a layer extending from the first buffer layer BF1 of the display layer DP. The second inorganic layer IF2 may be a layer extending from at least one of the first gate insulating layer GI1, the second gate insulating layer GI2, and the interlayer insulating layer ILD of the display layer DP. However, the disclosure is not limited thereto.

Although not shown in FIG. 8, the lower surface of the first inorganic layer IF1 may contact the upper surface of the substrate SUB of FIG. 6. The first inorganic layer IF1 may have multiple first holes HL1 that overlap the opening OP of the substrate SUB.

The second inorganic layer IF2 may be entirely disposed on the first inorganic layer IF1. The second inorganic layer IF2 may have multiple second holes HL2 overlapping the first holes HL1, respectively. The first holes HL1 and the second holes HL2 that overlap each other may constitute holes HL.

A planar size (e.g., size in a plan view) of each of the first holes HL1 may be smaller than a planar size (e.g., size in a plan view) of each of the second holes HL2. Accordingly, the first holes HL1 and the second holes HL2 may be arranged to alternate with each other and overlap each other without forming an undercut structure. However, embodiments according to the disclosure are not limited thereto.

The pads PAD may have a single-layer structure. The pads PAD may overlap the holes HL respectively and may be partially exposed through the holes HL. The pads PAD may include the same material as one of the first metal conductive layer SD1 and the second metal conductive layer SD2 of the display layer DP. For example, each of the pads PAD may have a two-layer structure of Ti/Al or a three-layer structure of Ti/Al/Ti.

The first insulating layer ISL1 and the third insulating layer ISL3 may be disposed on the pads PAD. The first insulating layer ISL1 and the third insulating layer ISL3 may entirely cover the pads PAD.

FIG. 9 is a schematic cross-sectional view showing the second embodiment 102 of the display device. FIG. 9 is a drawing showing another embodiment of FIG. 8.

The display device 102 according to this embodiment may be different from the display device 101 described above in that it further includes a pixel definition layer PDL′ and a via insulating layer VIA′. Therefore, duplicate description is briefly explained or not repeated.

Referring to FIG. 9, a via insulating layer VIA′, a pixel definition layer PDL′, a first insulating layer ISL1, and a third insulating layer ISL3 may be disposed on the pads PAD. The via insulating layer VIA′ and the pixel definition layer PDL′ may be disposed between the pads PAD and the first insulating layer ISL1. The via insulating layer VIA′ may cover the upper surfaces of the pads PAD and may flatten the upper surfaces of the pads PAD.

The via insulating layer VIA′ and at least one of the first via insulating layer VIA1 and the second via insulating layer VIA2 of the display layer DP of FIG. 5 may include equal material. The pixel definition layer PDL′ and the pixel definition layer PDL of the display layer DP may include equal material.

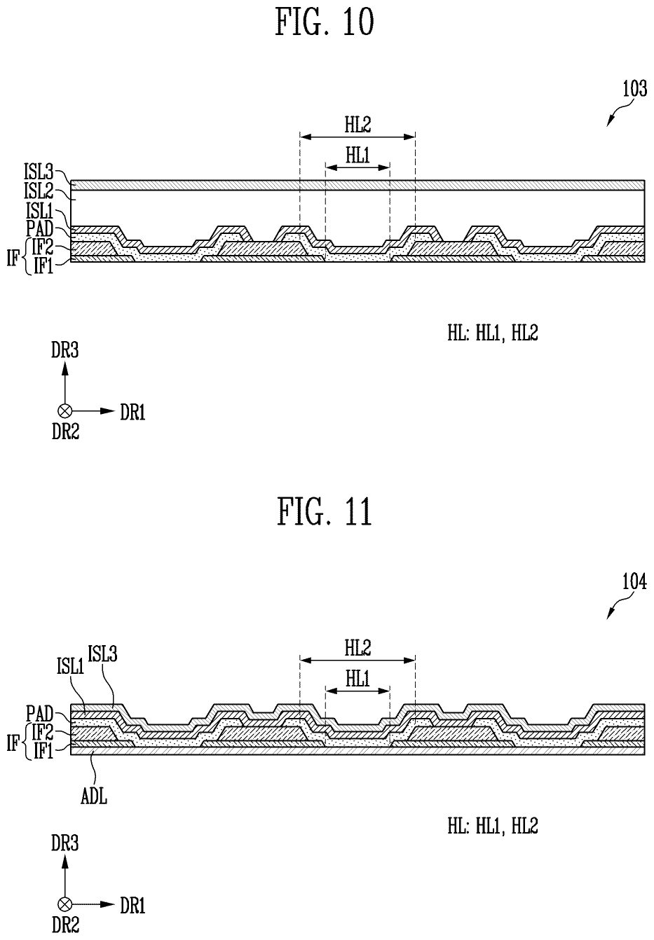

FIG. 10 is a schematic cross-sectional view showing the third embodiment 103 of a display device. FIG. 10 is a drawing showing another embodiment of FIG. 8.

The display device 103 according to this embodiment may be different from the display device 101 described above in that it further includes a second insulating layer ISL2. Therefore, duplicate description is briefly explained or not repeated.

Referring to FIG. 10, the first insulating layer ISL1, the second insulating layer ISL2, and the third insulating layer ISL3 may be disposed on the pads PAD. The second insulating layer ISL2 may be disposed between the first insulating layer ISL1 and the third insulating layer ISL3.

FIG. 11 is a schematic cross-sectional view showing the fourth embodiment 104 of the display device.

The display device 104 according to the embodiment may be different from the display device 101 described above in that it further includes a substrate adhesive layer ADL under the inorganic layer IF. Therefore, duplicate description is briefly explained or not repeated.

Referring to FIG. 11, the substrate adhesive layer ADL may be disposed on the lower surface of the inorganic layer IF and the pads PAD. Since the substrate adhesive layer ADL is further disposed on the lower surface of the inorganic layer IF and the pads PAD, the pads PAD may be attached to the substrate SUB without lifting during the manufacturing process.

The substrate adhesive layer ADL may include amorphous silicon, organic materials, etc. When the substrate adhesive layer ADL includes amorphous silicon, the amorphous silicon may be converted to polycrystalline silicon when the substrate SUB is etched. At this time, when the substrate adhesive layer ADL is converted to polycrystalline silicon, the conductivity of the substrate adhesive layer ADL may be improved. Accordingly, electrical connection between the pads PA and the circuit board CB may be facilitated.

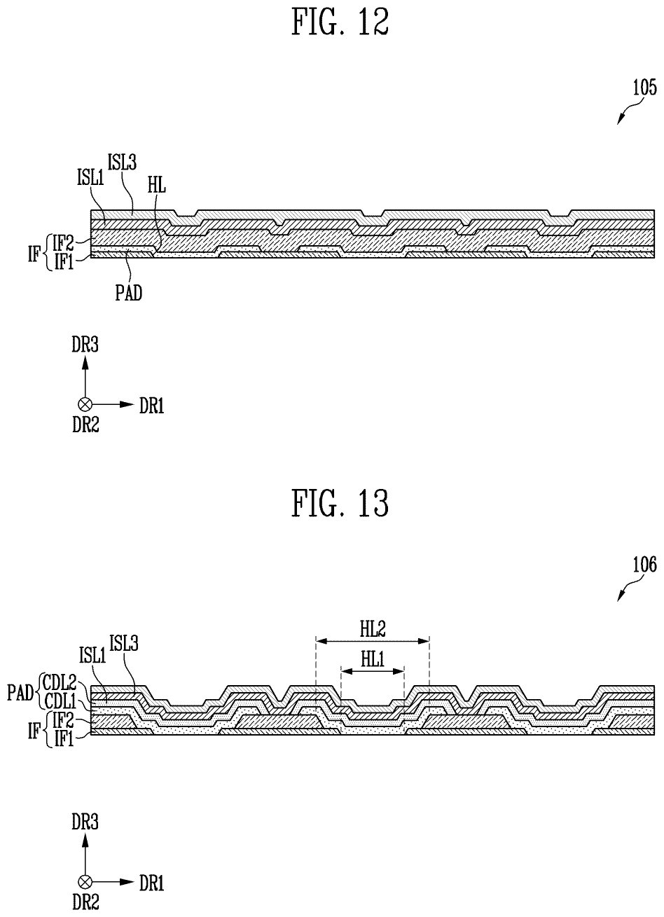

FIG. 12 is a schematic cross-sectional view showing the fifth embodiment 105 of the display device. FIG. 12 is a drawing showing another embodiment of FIG. 8.

The display device 105 according to the embodiment may be different from the display device 101 described above in that materials included in the conductive layer CDL are different from each other and only the first inorganic layer IF1 has holes HL. Therefore, duplicate description is briefly explained or not repeated.

Referring to FIG. 12, the pads PAD may be disposed between the first inorganic layer IF1 and the second inorganic layer IF2.

The pads PAD may have a single-layer structure. The pads PAD and one of the first gate conductive layer GAT1 and the second gate conductive layer GAT2 of the display layer DP may include equal material. For example, each of the pads PAD may be made of a single layer or multiple layers made of any one of molybdenum (Mo), aluminum (AL), chromium (Cr), gold (Au), titanium (Ti), nickel (Ni), neodymium (Nd), and copper (Cu), or an alloy thereof.

The first inorganic layer IF1 may have holes HL that overlap the opening OP of the substrate SUB. However, the second inorganic layer IF2 does not have holes HL and may entirely cover the upper surface of the pads PAD.

FIG. 13 is a schematic cross-sectional view showing the sixth embodiment 106 of the display device. FIG. 13 is a drawing showing another embodiment of FIG. 8.

The display device 106 according to this embodiment may be different from the display device 101 described above in that the pads PAD have a multilayer structure. Therefore, duplicate description is briefly explained or not repeated.

Referring to FIG. 13, each of the pads PAD may have a multi-layer structure.

For example, the pads PAD may include first conductive layers CDL1 and second conductive layers CDL2 respectively disposed on the first conductive layers CDL1. The first conductive layers CDL1 may contact the upper surface of the inorganic layer IF and may be partially exposed through the holes HL. The second conductive layers CDL2 may overlap the first conductive layers CDL1 and may be entirely contact the upper surfaces of the first conductive layers CDL1.

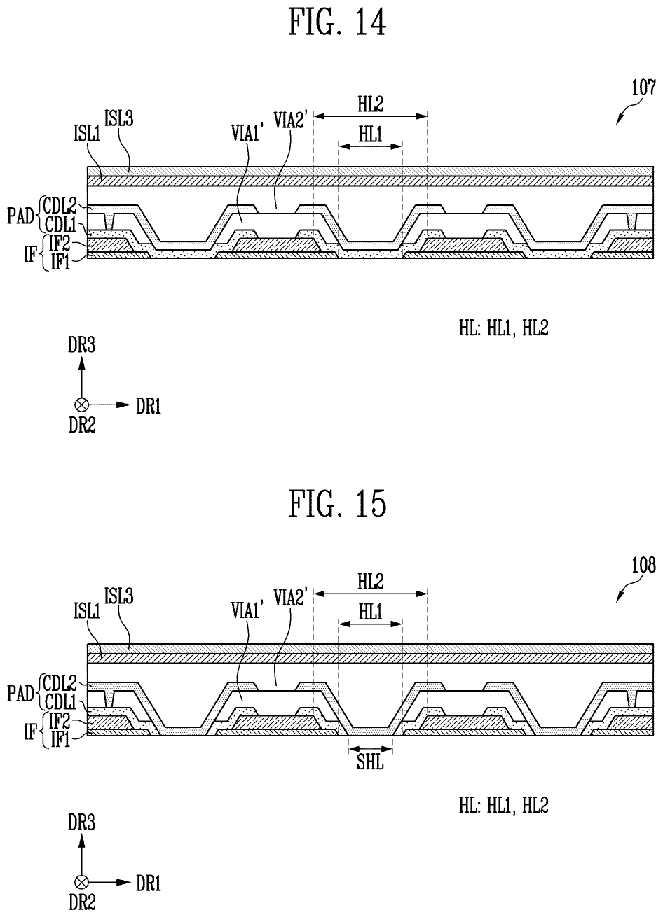

FIG. 14 is a schematic cross-sectional view showing the seventh embodiment 107 of the display device. FIG. 14 is a drawing showing another embodiment of FIG. 13.

The display device 107 according to the embodiment may be different from the display device 106 described above in that they further include a first via insulating layer VIA1′ between the first conductive layers CDL1 and the second conductive layers CDL2 included in the pads PAD and further include a second via insulating layer VIA2′ on the pads PAD. Therefore, duplicate description is briefly explained or not repeated.

Referring to FIG. 14, the first via insulating layer VIA1′ may be further disposed between the first conductive layers CDL1 and the second conductive layers CDL2 included in the pads PAD. The first via insulating layer VIA1′ may include a same material as the first via insulating layer VIA1 of the display layer DP of FIG. 5, or may be a layer extending from the first via insulating layer VIA1.

The first conductive layers CDL1 and the second conductive layers CDL2, which overlap each other by the first via insulating layer VIA1′, may only partially contact each other. For example, the first via insulating layer VIA1′ may define holes that overlap the first conductive layers CDL1, and the second conductive layers CDL2 may contact the first conductive layers CDL1 through the holes, respectively.

The second via insulating layer VIA2′ may cover the upper surfaces of the second conductive layers CDL2 and may be disposed on the first via insulating layer VIA1′. The second via insulating layer VIA2′ may include a same material as the second via insulating layer VIA2 of the display layer DP, or may extend from the second via insulating layer VIA2.

The first insulating layer ISL1 and the third insulating layer ISL3 may be disposed on the second via insulating layer VIA2′.

FIG. 15 is a schematic cross-sectional view showing the eighth embodiment 108 of the display device. FIG. 15 is a drawing showing another embodiment of FIG. 14.

The display device 108 according to the embodiment may be different from the display device 107 described above in that the first conductive layers CDL1 have sub-holes SHL and the second conductive layers CDL2 are exposed through the holes HL of the inorganic layer IF. Therefore, duplicate description is briefly explained or not repeated.

Referring to FIG. 15, the pads PAD may include the first conductive layers CDL1 and the second conductive layers CDL2 respectively disposed on the first conductive layers CDL1.

The first conductive layers CDL1 may contact the upper surface of the inorganic layer IF and may have sub-holes SHL overlapping the holes HL respectively in the third direction DR3. The planar size of each of the sub-holes SHL may be smaller than the planar size of each of the holes HL. For example, the planar size of each of the sub-holes SHL may be smaller than the planar size of each of the first holes HL1 and the second holes HL2. Accordingly, the first conductive layers CDL1 may also be partially exposed through the holes HL.

The second conductive layers CDL2 may overlap the first conductive layers CDL1 respectively and may be partially exposed through the holes HL and sub-holes SHL. For example, both the first conductive layers CDL1 and the second conductive layers CDL2 may be exposed through the holes HL. Accordingly, both the first conductive layers CDL1 and the second conductive layers CDL2 may be exposed through the holes HL and may be electrically connected to the circuit board CB of FIG. 6.

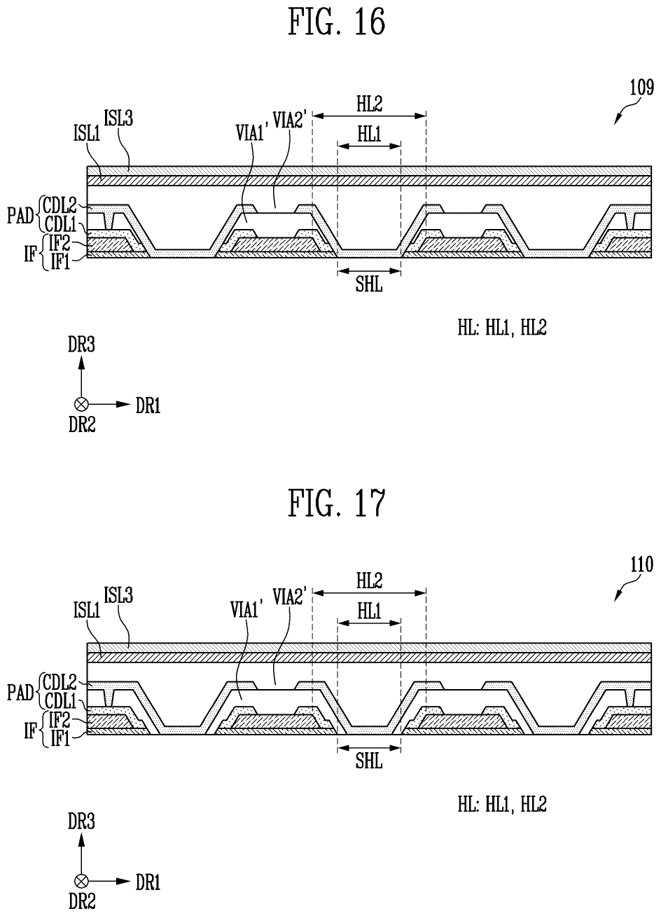

FIG. 16 is a schematic cross-sectional view showing the ninth embodiment 109 of the display device. FIG. 16 is a drawing showing another embodiment of FIG. 15.

The display device 109 according to this embodiment may be different from the display device 108 described above in the size of the sub-holes SHL of the first conductive layers CDL1. Therefore, duplicate description is briefly explained or not repeated.

Referring to FIG. 16, the pads PAD may include first conductive layers CDL1 and second conductive layers CDL2 respectively disposed on the first conductive layers CDL1.

The first conductive layers CDL1 may contact the upper surface of the inorganic layer IF and may have sub-holes SHL overlapping the holes HL respectively in the third direction DR3. The planar size of each of the sub-holes SHL may be substantially equal to the planar size of each of the first holes HL1, but may be smaller than the planar size of each of the second holes HL2. Accordingly, the first conductive layers CDL1 may not be exposed through the holes HL.

The second conductive layers CDL2 may overlap the first conductive layers CDL1 respectively and may be partially exposed through the holes HL and sub-holes SHL. For example, only the second conductive layers CDL2 may be partially exposed through the holes HL and sub-holes SHL, respectively. The area of the exposed portion of each of the second conductive layers CDL2 may be substantially equal to the area of each of the holes HL and sub-holes SHL. Accordingly, the second conductive layers CDL2 may be exposed through the holes HL respectively and may be electrically connected to the circuit board CB of FIG. 6.

FIG. 17 is a schematic cross-sectional view showing a tenth embodiment 110 of a display device. FIG. 17 is a drawing showing another embodiment of FIG. 16.

The display device 110 according to this embodiment may be different from the display device 109 described above in whether the first via insulating layer VIA1′ is exposed. Therefore, duplicate description is briefly explained or not repeated.

Referring to FIG. 17, the pads PAD may include the first conductive layers CDL1 and the second conductive layers CDL2 respectively disposed on the first conductive layers CDL1.

The first via insulating layer VIA1′ may be disposed between the first conductive layers CDL1 and the second conductive layers CDL2. The first via insulating layer VIA1′ may be partially exposed through the holes HL and sub-holes SHL. The planar size of each of the sub-holes SHL and the planar size of each of the first holes HL1 may be substantially equal, and the planar size of the hole of the first via insulating layer VIA1′ may be smaller than the planar size of each of the sub-holes SHL so that the first via insulating layer VIA1′ may be exposed through the holes HL.

The second conductive layers CDL2 may overlap the first conductive layers CDL1 respectively and may be partially exposed through the holes HL and sub-holes SHL. The area of exposed portion of each of the second conductive layers CDL2 due to the first via insulating layer VIA1′ may be smaller than the area of each of the holes HL and sub-holes SHL.

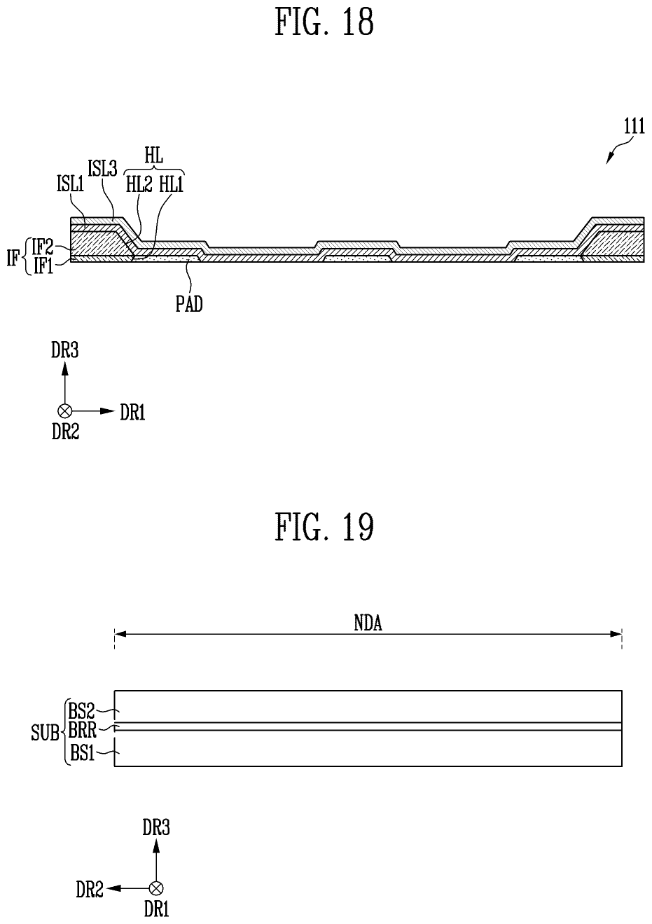

FIG. 18 is a schematic cross-sectional view showing the eleventh embodiment 111 of the display device. FIG. 18 is a drawing showing another embodiment of FIG. 8.

The display device 111 according to the embodiment may be different from the display device 101 described above in the area of the hole HL of the inorganic layer IF. Therefore, duplicate description is briefly explained or not repeated.

Referring to FIG. 18, the inorganic layer IF may include a first inorganic layer IF1 and a second inorganic layer IF2 disposed on the first inorganic layer IF1.

For example, the first inorganic layer IF1 may have a first hole HL1 that overlaps the opening OP of the substrate SUB. The first hole HL1 may overlap multiple pads PAD. The second inorganic layer IF2 may have a second hole HL2 that overlaps the first hole HL1. The second hole HL2 may also overlap multiple pads PAD. The first hole HL1 and the second hole HL2 that overlap each other may form one hole HL.

The pads PAD may overlap the hole HL and may be exposed through the hole HL. For example, the pads PAD may be exposed through the hole HL to contact the circuit board CB of FIG. 6.

FIGS. 19 to 29 are schematic drawings showing a manufacturing method of a display device according to an embodiment of the disclosure.

FIGS. 19 to 29 illustrate a manufacturing method of the display device DD according to the embodiment described above with reference to FIGS. 1 to 7. Duplicate description is briefly explained or not repeated.

Referring to FIG. 19, the substrate SUB may be formed entirely in the display area DA and the non-display area NDA of FIG. 4. A first base substrate BS1 may be formed. The first base substrate BS1 may be formed of polyimide. The barrier layer BRR may be formed on the first base substrate BS1. The barrier layer BRR may be formed of an inorganic material. The second base substrate BS2 may be disposed on the barrier layer BRR. The second base substrate BS2 may be formed of polyimide like the first base substrate BS1.

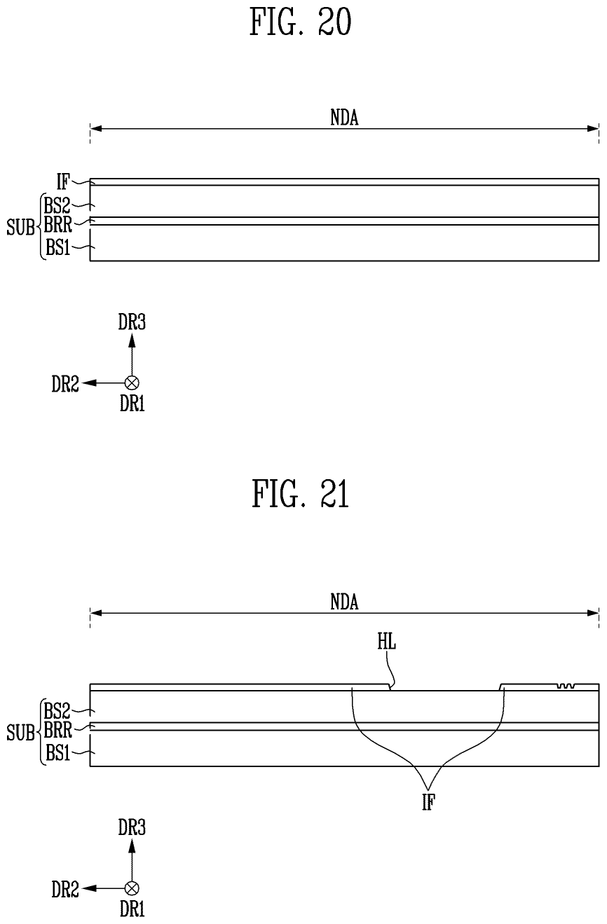

Referring to FIG. 20, the inorganic layer IF may be disposed on the substrate SUB. The inorganic layer IF may be disposed entirely in the display area DA and the non-display area NDA of FIG. 6. At this time, the inorganic layer IF may include at least one of the first buffer layer BF1, the first gate insulating layer GI1, the second gate insulating layer GI2, and the interlayer insulating layer ILD of the display layer DP of FIG. 5.

The substrate adhesive layer ADL of FIG. 11 may be further disposed on the substrate SUB, and the inorganic layer IF may contact the substrate SUB through the substrate adhesive layer ADL (see FIG. 11). Lifting of the pads PAD disposed on the inorganic layer IF can be prevented. However, the disclosure is not limited thereto, and the substrate adhesive layer ADL disposed between the substrate SUB and the inorganic layer IF may be omitted or may be removed together with the substrate SUB.

Referring to FIG. 21, multiple holes HL may be formed in the inorganic layer IF. At this time, the plurality of holes HL may be formed simultaneously with a contact hole formed in at least one of the first buffer layer BF1, the first gate insulating layer GI1, the second gate insulating layer GI2, and the interlayer insulating layer ILD of the display layer DP of FIG. 5.

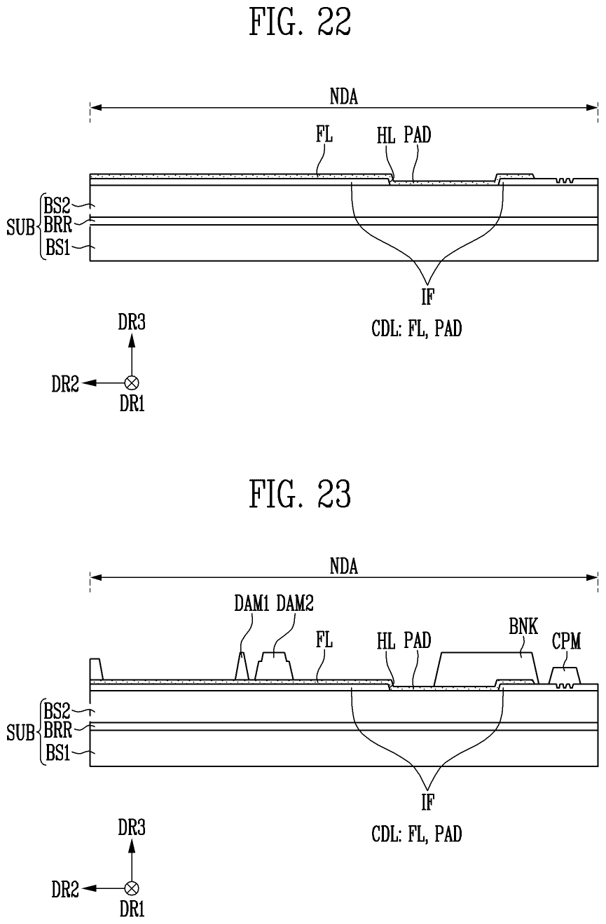

Referring to FIG. 22, the conductive layer CDL may be disposed on the inorganic layer IF. The conductive layer CDL may be disposed simultaneously with at least one of the first metal conductive layer SD1 and the second metal conductive layer SD2 of the display layer DP and may be formed with a same material. For example, the conductive layer CDL may be disposed simultaneously with one of the first metal conductive layer SD1 and the second metal conductive layer SD2 of the display layer DP and may be formed with a same material, or may be a multi-layer structure formed simultaneously with both the first metal conductive layer SD1 and the second metal conductive layer SD2 and formed with a same material. However, the disclosure is not limited thereto, and the conductive layer CDL may be formed simultaneously with at least one of the first gate conductive layer GAT1 and the second gate conductive layer GAT2 and may be formed with a same material.

For example, the conductive layer CDL may be formed as a two-layer structure of Ti/Al or a three-layer structure of Ti/Al/Ti. However, the disclosure is not limited thereto, and the conductive layer CDL may be formed as a single layer or multiple layers made of any one of molybdenum (Mo), aluminum (AL), chromium (Cr), gold (Au), titanium (Ti), nickel (Ni), neodymium (Nd), and copper (Cu), or an alloy thereof.

The conductive layer CDL may be patterned to form signal lines FL and pads PAD. The signal lines FL may be electrically connected to the display layer DP or may be formed to extend from the display layer DP. The pads PAD may overlap the holes HL of the inorganic layer IF respectively. Accordingly, the pads PAD may contact the upper surface of the substrate SUB at portions that overlap the holes HL of the inorganic layer IF in the third direction DR3.

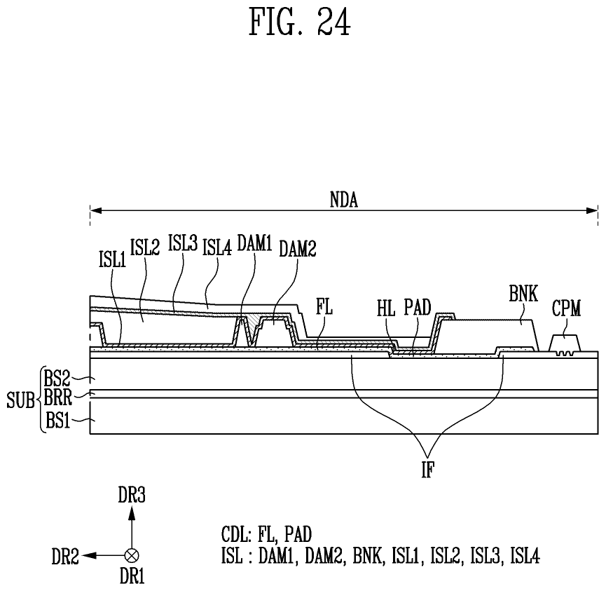

Referring to FIGS. 23 and 24, the insulating layer ISL may be disposed on the inorganic layer IF and the conductive layer CDL. The insulating layer ISL may be disposed to entirely cover the upper surfaces of the pads PAD.

Referring to FIG. 23, a first dam DAM1, a second dam DAM2, a bank BNK, and a crack prevention layer CPM may be disposed on the conductive layer CDL.

The second dam DAM2 may be disposed further away from the display layer DP than the first dam DAM1, the bank BNK may be disposed further away from the display layer DP than the second dam DAM2, and the crack prevention layer CPM may be disposed further away from the display layer DP than bank BNK. In FIG. 23, the bank BNK is shown as partially overlapping the pads PAD in the third direction DR3, but embodiments according to the disclosure are not limited thereto, and the pads PAD may overlap the first dam DAM1 and the second dam DAM2 in the third direction DR3.

Each of the first dam DAM1 and the second dam DAM2 may be formed in a multi-layer structure, and may be formed simultaneously with at least one of the first via insulating layer VIA1, the second via insulating layer VIA2, and the pixel definition layer PDL of the display layer DP.

The bank BNK may be formed in a multi-layer structure, and may be formed simultaneously with at least one of the first via insulating layer VIA1, the second via insulating layer VIA2, and the pixel definition layer PDL of the display layer DP.

The crack prevention layer CPM may be formed in a single layer structure, and may be formed simultaneously with one of the first via insulating layer VIA1, the second via insulating layer VIA2, and the pixel definition layer PDL of the display layer DP.

Here, further referring to FIG. 5, after the first via insulating layer VIA1 and the second via insulating layer VIA2 of the display layer DP are formed, a light emitting element LEL including an anode electrode ANO, a light emitting layer EL, and a cathode electrode CAT may be disposed on the second via insulating layer VIA2. The pixel definition layer PDL may be disposed on the anode electrode ANO before the light emitting layer EL is disposed.

Referring to FIG. 24, first to fourth insulating layers ISL1, ISL2, ISL3, and ISL4 may be disposed on the first dam DAM1, the second dam DAM2, and the bank BNK.

The first insulating layer ISL1 may be formed simultaneously with the first inorganic encapsulation layer IEL1 of the display layer DP and may be formed with a same material. The first insulating layer ISL1 may be a layer extending from the first inorganic encapsulation layer IEL1 of the display layer DP. For example, the first insulating layer ISL1 may be formed of an inorganic material.

The second insulating layer ISL2 may be formed simultaneously with the organic encapsulation layer OEL of the display layer DP and may be formed with a same material. The second insulating layer ISL2 may be a layer extending from the organic encapsulation layer OEL of the display layer DP. For example, the second insulating layer ISL2 may be formed of an organic material.

The third insulating layer ISL3 may be formed simultaneously with the second inorganic encapsulation layer IEL2 of the display layer DP and may be formed with a same material. The third insulating layer ISL3 may be a layer extending from the second inorganic encapsulation layer IEL2 of the display layer DP. For example, the third insulating layer ISL3 may be formed of an inorganic material.

The fourth insulating layer ISL4 may be formed simultaneously with one of the first sensing insulating layer YILD and the second sensing insulating layer YPVX of the display layer DP and may be formed with a same material. The fourth insulating layer ISL4 may be a layer extending from one of the first sensing insulating layer YILD and the second sensing insulating layer YPVX of the display layer DP.

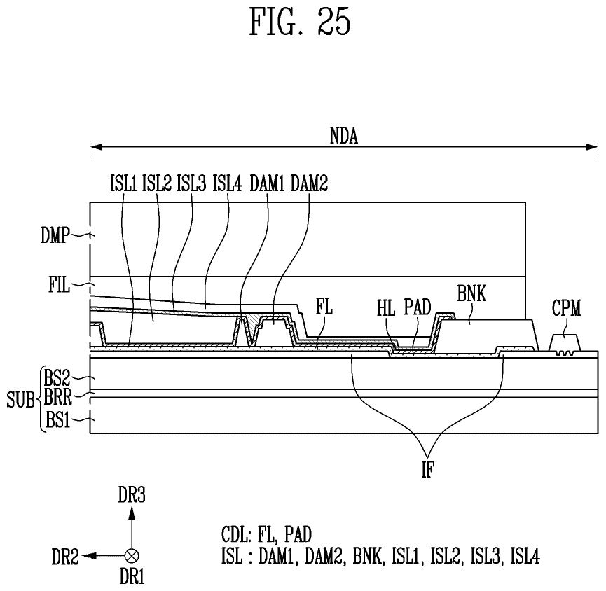

Referring to FIG. 25, a filling layer FIL may be disposed on the insulating layer ISL. A damping layer DMP may be disposed on top of the filling layer FIL. The damping layer DMP may be formed of a material that functions as a polarizer, and the filling layer FIL may be formed of an organic material. However, embodiments according to the disclosure are not limited thereto.

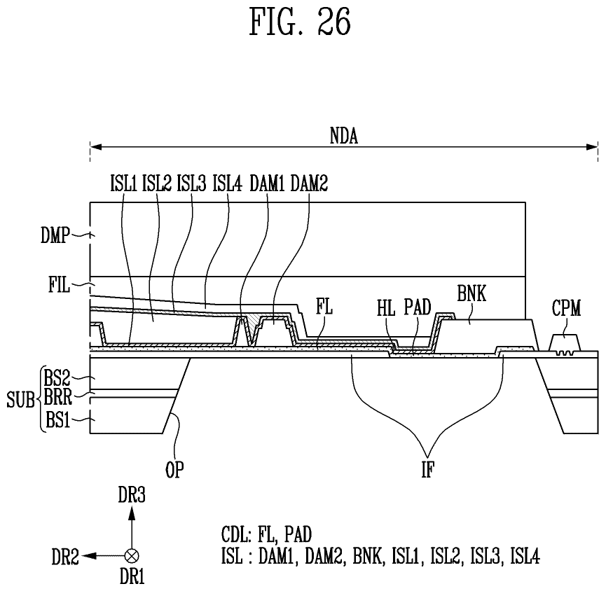

Referring to FIG. 26, an opening OP may be formed in the substrate SUB. The opening OP may be formed to overlap the holes HL of the inorganic layer IF in the third direction DR3. For example, the lower surface of the inorganic layer IF and the lower surface of the pads PAD may be exposed through the opening OP.

The opening OP may be formed by partially removing the substrate SUB by irradiating a laser to the substrate SUB. However, the disclosure is not limited thereto, and in another embodiment, the opening OP may be formed in the substrate SUB through a dry etching process or a wet etching process.

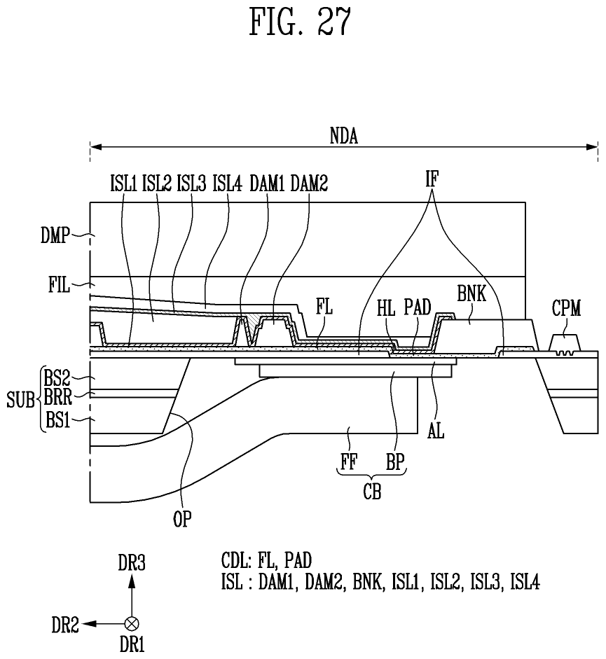

Referring to FIG. 27, the circuit board CB may be provided toward the bottom direction of the substrate SUB. The circuit board CB may be attached to the lower surface of the inorganic layer IF and the lower surfaces of the pads PAD through the adhesive layer AL.

The circuit board CB may be at least partially disposed inside the opening OP of the board SUB. Since the circuit board CB is provided toward the bottom direction of the substrate SUB, the circuit board CB may be spaced apart from the pads PAD and the insulating layer ISL with the inorganic layer IF interposed therebetween.

The circuit board CB may be electrically connected to the pads PAD exposed through the holes HL of the inorganic layer IF. A circuit board CB may include bumps BP and a flexible film FF. The pads PAD and bumps BP exposed through the holes HL may be electrically connected to each other through a conductive ink layer CIL, which will be described later.

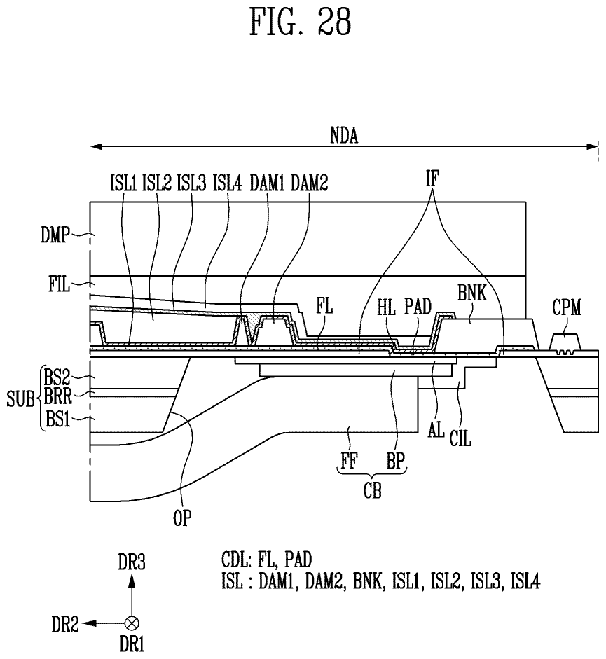

Referring to FIG. 28, the conductive ink layer CIL may be disposed on the lower surfaces of the pads PAD and the side surfaces and lower surfaces of the bumps BP.

The conductive ink layer CIL may be in direct contact with each of the pads PAD and the bumps BP included in the circuit board CB. As the conductive ink layer CIL is in direct contact each of the pads PAD and the circuit board CB, the pads PAD and the circuit board CB may be electrically connected to each other.

An ink including a conductive material may be applied on the lower surfaces of the pads PAD, the surface of the bump BP, and the surface of the flexible film FF. The ink may include metal particles. For example, the ink containing the conductive material may include silver and copper particles. Thereafter, the ink containing the conductive material may be solidified through a sintering process. The sintering process is an optical sintering process. The solidified ink entirely applied may be patterned to form the conductive ink layer CIL.

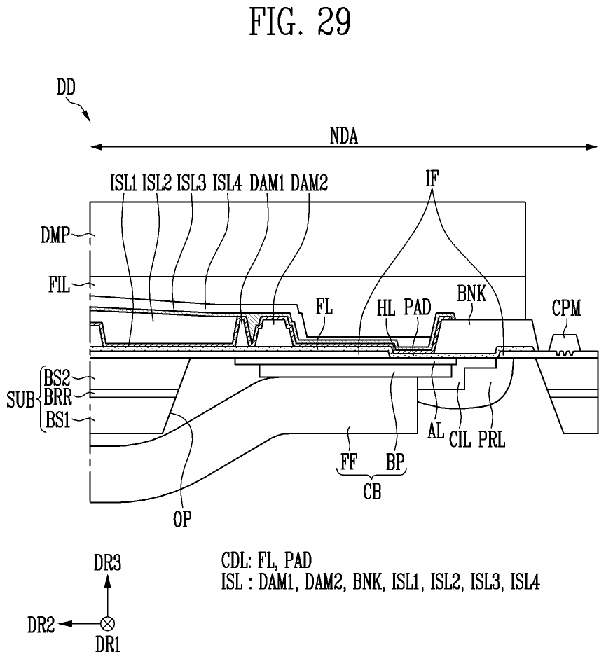

Referring to FIG. 29, a protective resin layer PRL may be formed on the lower surface of the conductive ink layer CIL. The protective resin layer PRL may be formed to cover the conductive ink layer CIL. The protective resin layer PRL may be formed of an organic material.

An organic material may be applied to the surface of the conductive ink layer CIL. The organic material applied to the surface may be cured to form the protective resin layer PRL. Accordingly, the display device DD may be formed.

An opening OP may be formed in the substrate SUB, and the circuit board CB may be electrically connected to the pads PAD through the opening OP toward the bottom direction of the substrate SUB. Accordingly, since the circuit board CB does not need to be bent, the area of dead space may be reduced. Since no separate process or mask is added to form the pads PAD electrically connected to the circuit board CB, manufacturing process costs may be reduced and manufacturing process efficiency may be improved.

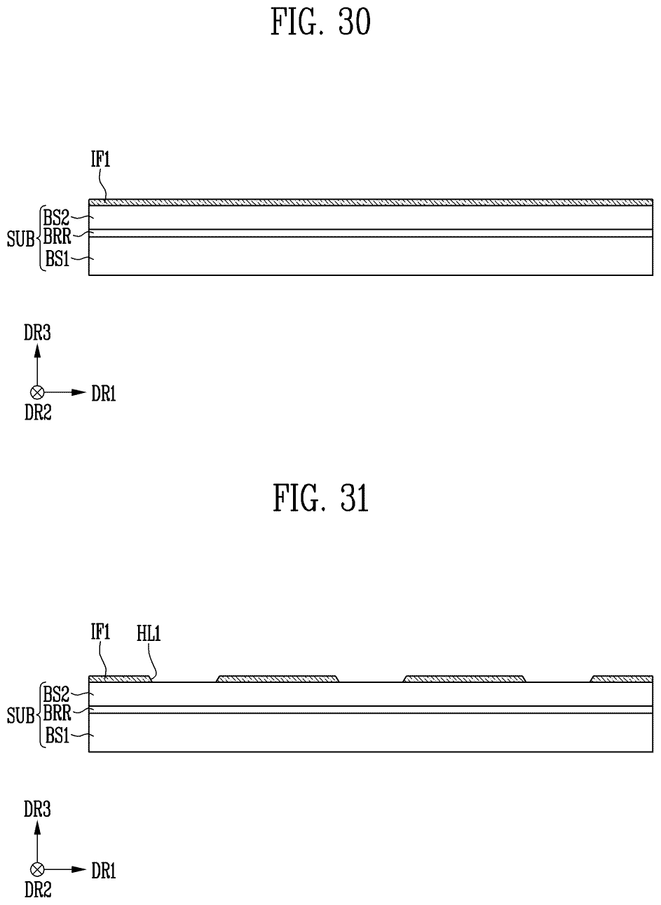

FIGS. 30 to 36 are schematic drawings showing a first embodiment of a manufacturing method of a display device.

FIGS. 30 to 36 illustrate a manufacturing method of the display device 101 according to the embodiment described above with reference to FIG. 8. Duplicate description is briefly explained or not repeated.

Referring to FIG. 30, a first inorganic layer IF1 may be disposed on the substrate SUB. The first inorganic layer IF1 may contact the upper surface of the substrate SUB.

Referring to FIG. 31, multiple first holes HL1 may be formed in the first inorganic layer IF1. Each of the first holes HL1 may be spaced apart from each other.

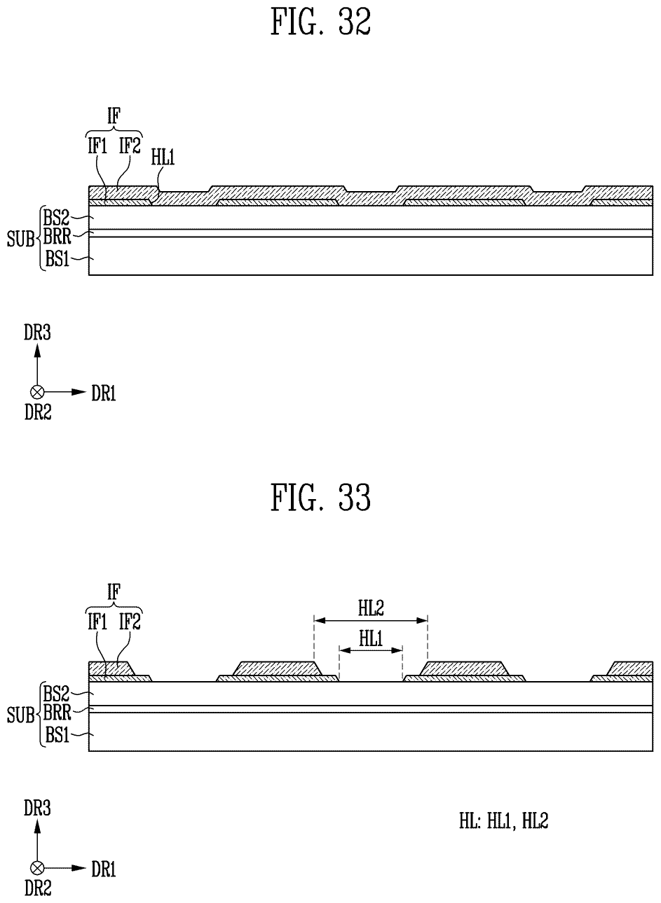

Referring to FIG. 32, a second inorganic layer IF2 may be disposed on the first inorganic layer IF1. The second inorganic layer IF2 may be entirely disposed on the first inorganic layer IF1 and the first holes HL1.

Referring to FIG. 33, multiple second holes HL2 may be formed in the second inorganic layer IF2. The second holes HL2 may overlap the first holes HL1 in the third direction DR3, respectively. The first holes HL1 and the second holes HL2 that overlap each other in the third direction DR3 may form one hole HL.

The planar size of each of the second holes HL2 may be larger than the planar size of each of the first holes HL1. Accordingly, the second holes HL2 and the first holes HL1 may overlap without being misaligned during the manufacturing process.

The first inorganic layer IF1 and the second inorganic layer IF2 may form one inorganic layer IF.

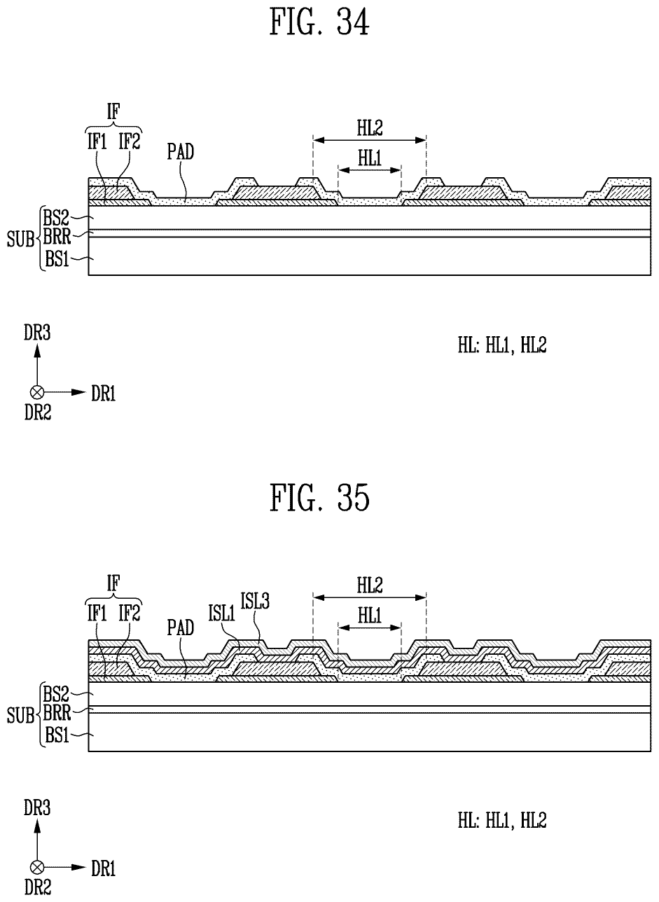

Referring to FIG. 34, the pads PAD may be disposed on the inorganic layer IF. The pads PAD may be patterned to overlap the holes HL.

Referring to FIG. 35, a first insulating layer ISL1 and a third insulating layer ISL3 may be formed on the inorganic layer IF and the pads PAD. Each of the first insulating layer ISL1 and the third insulating layer ISL3 may be formed of an inorganic material and may entirely cover the upper surface of the inorganic layer IF and the upper surfaces of the pads PAD.

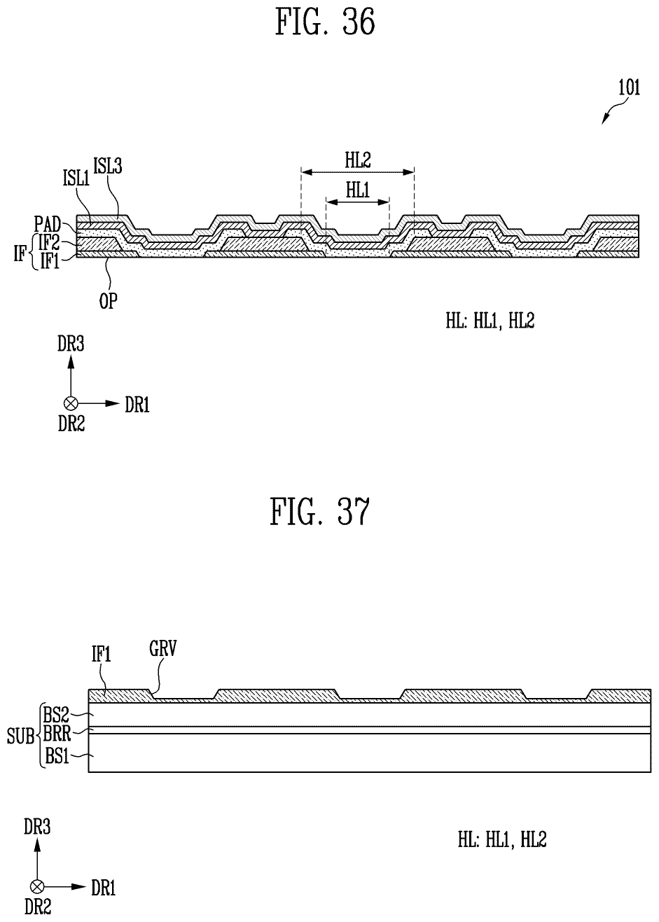

Referring to FIG. 36, a portion of the substrate SUB disposed on the lower surface of the inorganic layer IF and the lower surfaces of the pads PAD may be removed to form the opening OP. The opening OP may entirely overlap the pads PAD.

FIGS. 37 to 39 are schematic drawings showing a second embodiment of a manufacturing method of a display device. FIGS. 37 to 39 are schematic drawings showing another embodiment of FIGS. 30 to 36.

FIGS. 37 to 39 illustrate a manufacturing method of the display device 101 according to the embodiment described above with reference to FIG. 8. Duplicate description is briefly explained or not repeated.

Referring to FIG. 37, a first inorganic layer IF1 may be disposed on the substrate SUB. Grooves GRV may be formed in the first inorganic layer IF1 instead of holes penetrating the first inorganic layer IF1. For example, the first inorganic layer IF1 may not expose the upper surface of the substrate SUB.

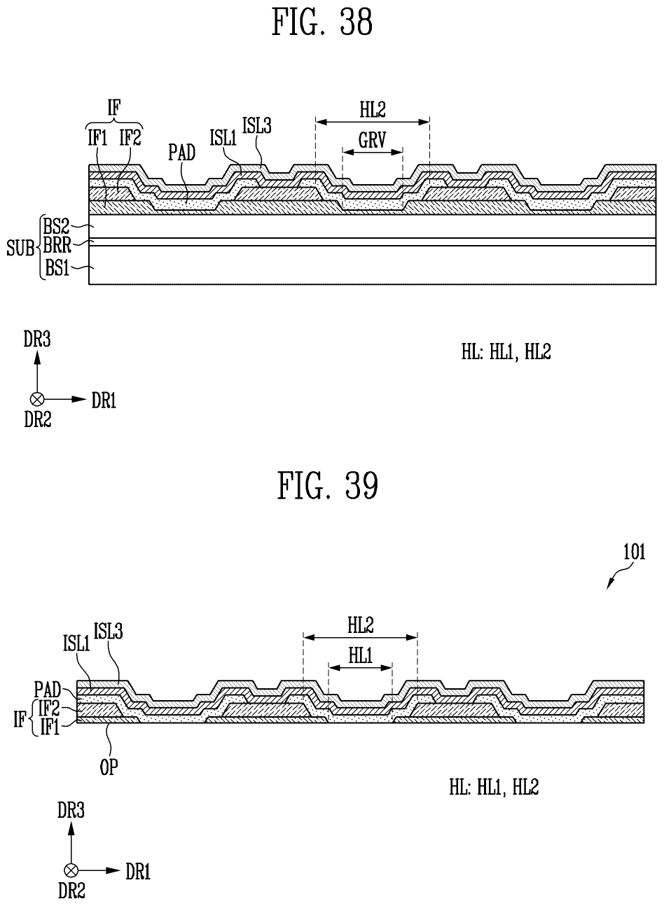

Referring to FIG. 38, the second inorganic layer IF2 may be disposed on the first inorganic layer IF1, the pads PAD may be disposed on the second inorganic layer IF2, and the first insulating layer ISL1 and the third insulating layer ISL3 may be disposed on the pads PAD. Since the holes HL are not formed in the first inorganic layer IF1, the lower surfaces of the pads PAD may not contact the substrate SUB due to the first inorganic layer IF1.

Referring to FIG. 39, a portion of the substrate SUB and the first inorganic layer IF1 may be removed to form the opening OP and the first holes HL1.

Not only the substrate SUB but also the first inorganic layer IF1 may be removed to expose the lower surfaces of the pads PAD. Accordingly, the opening OP may be disposed in the substrate SUB, and the first holes HL1 may be formed in the first inorganic layer IF1, overlapping the opening OP and the second holes HL2 in the third direction DR3. For example, a portion of the first inorganic layer IF1 that overlaps the grooves GRV may be removed to form the grooves GRV into the first holes HL1.

In case that layers are stacked on the substrate SUB, the pads PAD and the substrate SUB may not be in direct contact each other, thereby preventing contamination of the lower surfaces of the pads PAD. Accordingly, the reliability of the display device 101 may be improved.

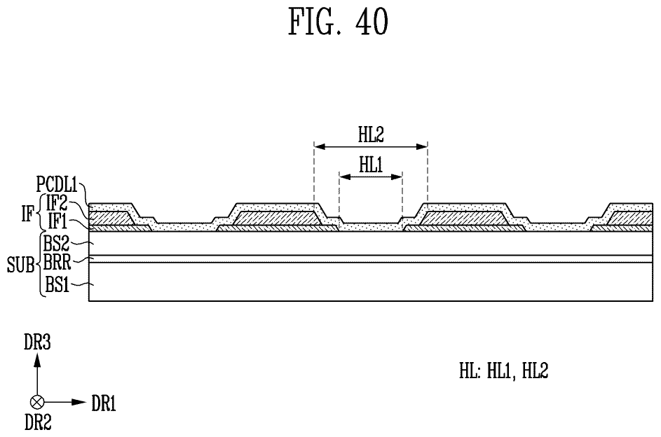

FIGS. 40 to 46 are schematic drawings showing a third embodiment of a manufacturing method of a display device. FIGS. 40 to 46 are schematic drawings showing another embodiment of FIGS. 30 to 36.

FIGS. 40 to 46 illustrate a manufacturing method of the display device 107 according to the embodiment described above with reference to FIG. 14. Duplicate description is briefly explained or not repeated.

Referring to FIG. 40, an inorganic layer IF may be disposed on the substrate SUB, and holes HL may be formed in the inorganic layer IF.

A first preliminary conductive layer PCDL1 that overlaps the inorganic layer IF and the holes HL may be formed entirely on the upper surface of the inorganic layer IF. The first preliminary conductive layer PCDL1 may be formed simultaneously with the first metal conductive layer SD1 of the display layer DP of FIG. 5 and may be formed of the same material.

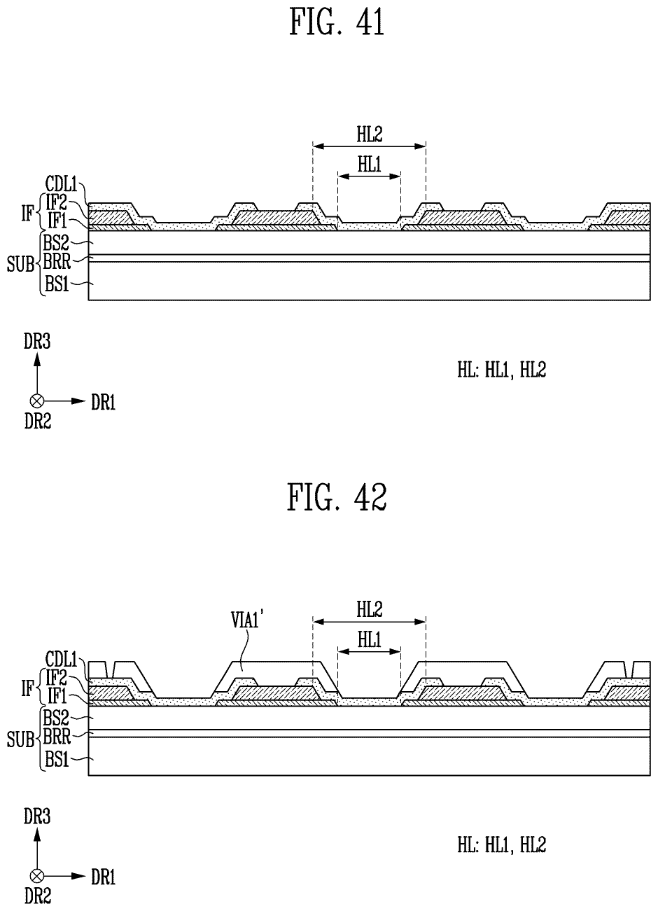

Referring to FIG. 41, the first conductive layers CDL1 overlapping the holes HL respectively may be formed by patterning the first preliminary conductive layer PCDL1. For example, a portion of the first preliminary conductive layer PCDL1 that does not overlap the holes HL may be removed.

Referring to FIG. 42, a first via insulating layer VIA1′ may be disposed on the first conductive layers CDL1. The first via insulating layer VIA1′ may be formed simultaneously with the first via insulating layer VIA1 of the display layer DP of FIG. 5 and may be of the same material. The first via insulating layer VIA1′ may extend from the first via insulating layer VIA1′ of the display layer DP. After the first via insulating layer VIA1′ is formed entirely on the first conductive layers CDL1, a portion overlapping the holes HL and a portion for connection to the first conductive layers CDL1 may be removed. Accordingly, holes and contact holes that overlap the holes HL of the inorganic layer may be formed in the first via insulating layer VIA1′.

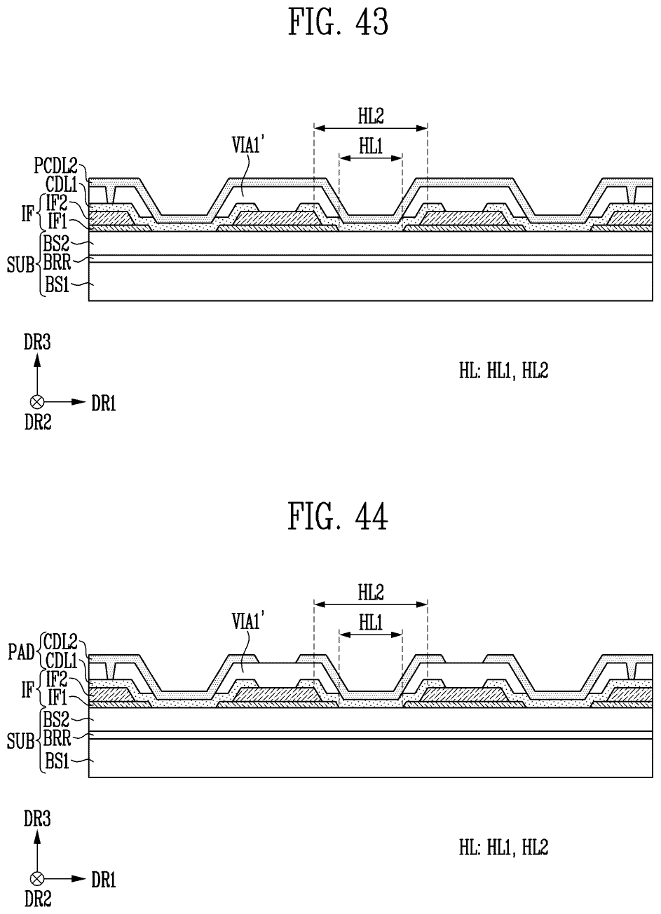

Referring to FIG. 43, a second preliminary conductive layer PCDL2 may be disposed on the first via insulating layer VIA1′. The second preliminary conductive layer PCDL2 may be disposed entirely on the first via insulating layer VIA1′ and the first conductive layers CDL1. The second preliminary conductive layer PCDL2 may be formed simultaneously with the second metal conductive layer SD2 of the display layer DP of FIG. 5 and may be formed with a same material.

Referring to FIG. 44, second conductive layers CDL2 overlapping the holes HL respectively may be formed by patterning the second preliminary conductive layer PCDL2. For example, a portion of the second preliminary conductive layer PCDL2 that does not overlap the holes HL may be removed, thereby forming second conductive layers CDL2 that overlaps the first conductive layers CDL1 respectively.

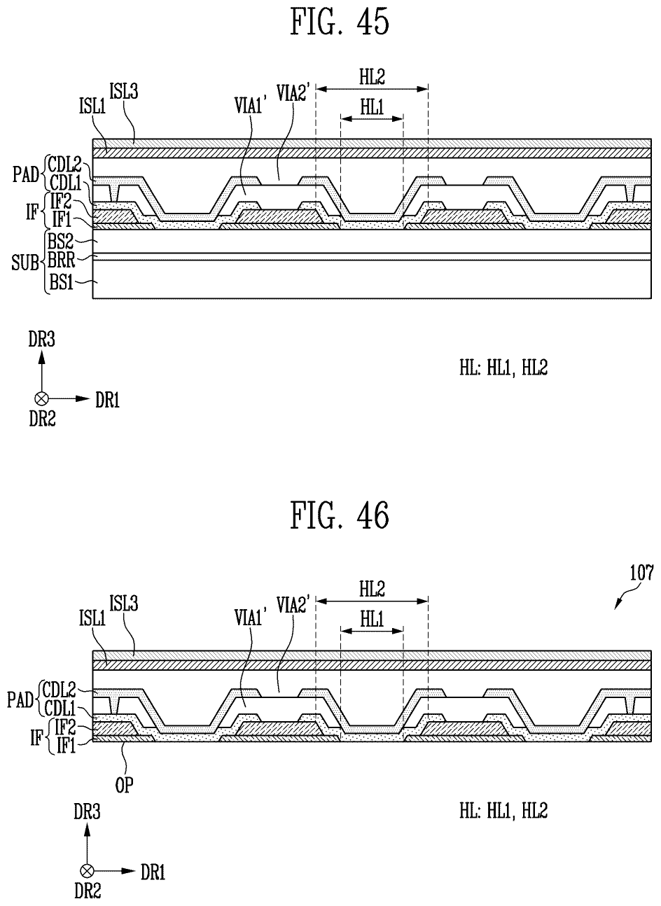

Referring to FIG. 45, the second via insulating layer VIA2′ may be entirely disposed on the second conductive layers CDL2 and the first via insulating layer VIA1′, and the first insulating layer ISL1 and the third insulating layer ISL3 may be entirely disposed on the second via insulating layer VIA2′. The second via insulating layer VIA2′ may be formed simultaneously with the second via insulating layer VIA2 of the display layer DP and may be made of the same material. The second via insulating layer VIA2′ may extend from the second via insulating layer VIA2 of the display layer DP.

Referring to FIG. 46, a portion of the substrate SUB that overlaps the holes HL of the inorganic layer IF may be removed. For example, a portion of the substrate SUB may be removed to form the opening OP that overlaps the holes HL of the inorganic layer IF. Lower surfaces of the first conductive layers CDL1 included in the pads PAD may be exposed through the opening OP. Accordingly, the pads PAD and the circuit board CB of FIG. 6 may be electrically connected to each other through the opening OP.

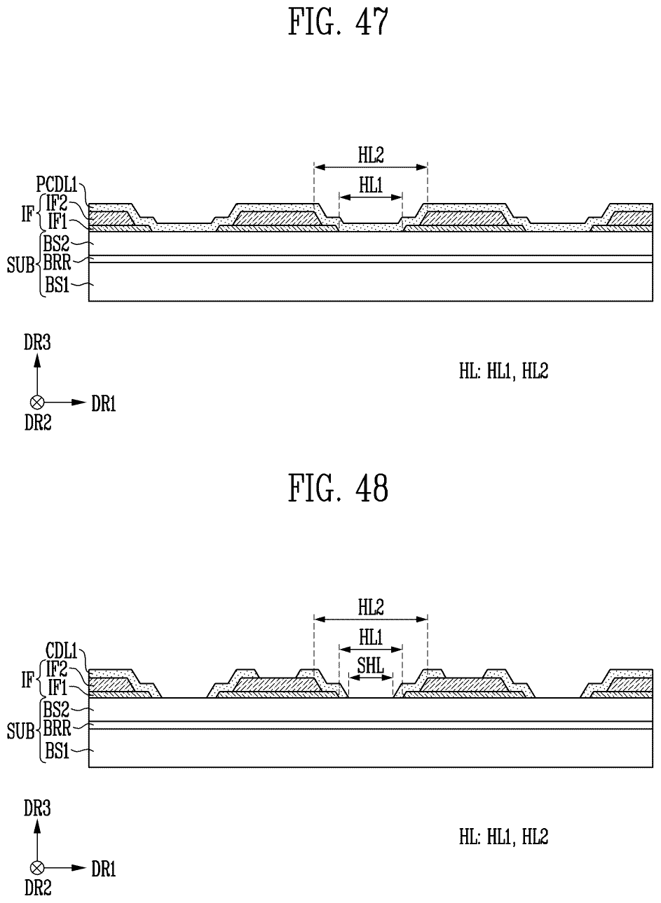

FIGS. 47 to 51 are schematic drawings showing a fourth embodiment of a manufacturing method of a display device. FIGS. 47 to 51 are schematic drawings showing another embodiment of FIGS. 30 to 36.

FIGS. 47 to 51 illustrate a manufacturing method of the display device 108 according to the embodiment described above with reference to FIG. 15. Duplicate description is briefly explained or not repeated.

Referring to FIG. 47, the first preliminary conductive layer PCDL1 may be entirely formed on the substrate SUB and the inorganic layer IF.

Referring to FIG. 48, the first preliminary conductive layer PCDL1 may be patterned to form first conductive layers CDL1 that partially overlap the holes HL. Sub-holes SHL overlapping the holes HL respectively, may be formed in the first conductive layers CDL1.

The planar size of each of the sub-holes SHL may be smaller than the planar size of each of the first holes HL1. Accordingly, a portion of each of the first conductive layers CDL1 may contact the substrate SUB through the hole HL. However, the disclosure is not limited thereto. In another embodiment, the planar size of each of the sub-holes SHL may be substantially equal to the planar size of each of the first holes HL1 (see FIGS. 16 and 17). For example, the first conductive layers CDL1 may be disposed only on the inorganic layer IF without contacting the substrate SUB.

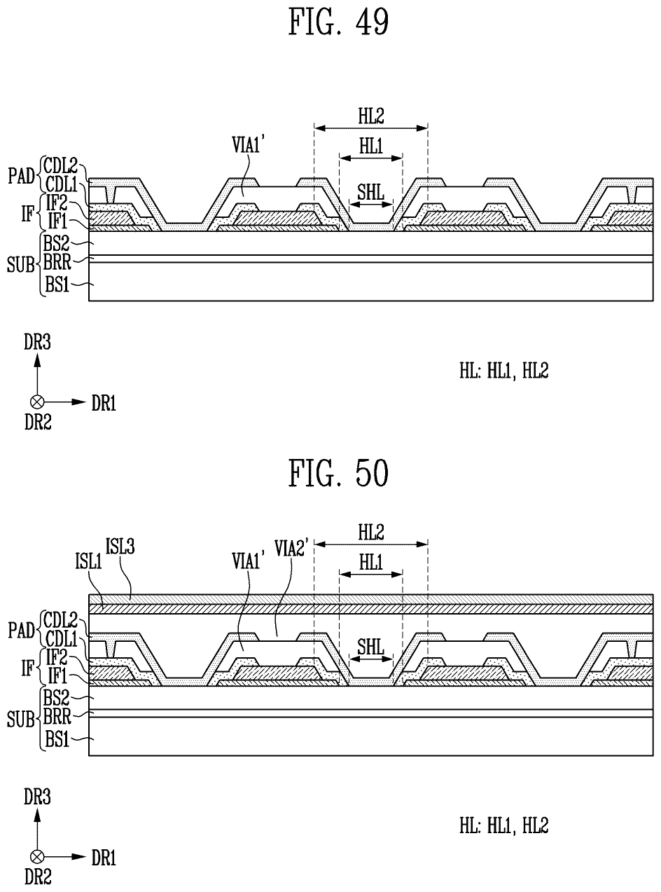

Referring to FIG. 49, a first via insulating layer VIA1′ and second conductive layers CDL2 may be disposed on the first conductive layers CDL1. The second conductive layers CDL2 may be disposed on the first conductive layers CDL1 with the first via insulating layer VIA1′ interposed therebetween.

The second conductive layers CDL2 may overlap the holes HL and sub-holes SHL respectively. For example, the second conductive layers CDL2 may contact the upper surface of the substrate SUB through the holes HL and sub-holes SHL.

Referring to FIG. 50, the second via insulating layer VIA2′, the first insulating layer ISL1, and the third insulating layer ISL3 may be disposed on the second conductive layers CDL2 and the first via insulating layer VIA1′.

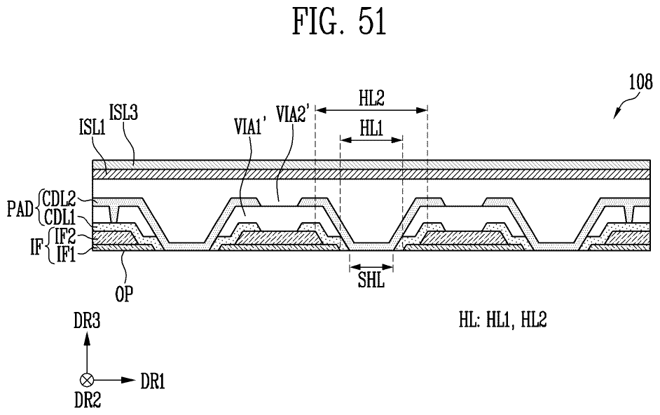

Referring to FIG. 51, a portion of the substrate SUB that overlaps the holes HL of the inorganic layer IF may be removed. For example, a portion of the substrate SUB may be removed to form the opening OP that overlaps the holes HL of the inorganic layer IF. Lower surfaces of the second conductive layers CDL2 included in the pads PAD may be exposed through the opening OP. Accordingly, the second conductive layers CDL2 may be electrically connected to the circuit board CB of FIG. 6.

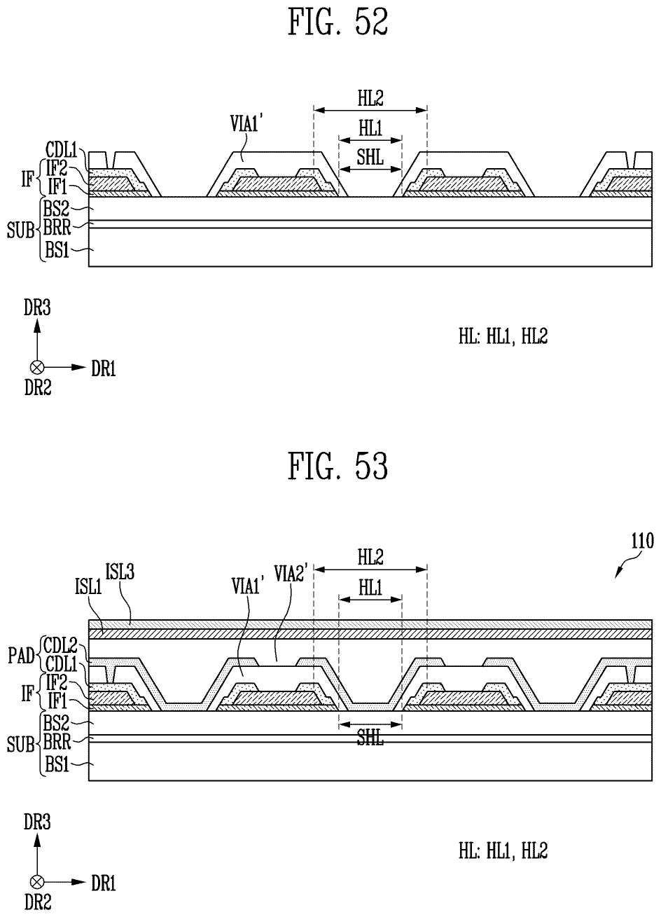

FIGS. 52 to 54 are schematic drawings showing a fifth embodiment of a manufacturing method of a display device. FIGS. 52 to 54 are schematic drawings showing another embodiment of FIGS. 47 to 51.

FIGS. 52 to 54 illustrate a manufacturing method of the display device 110 according to the embodiment described above with reference to FIG. 17. Duplicate description is briefly explained or not repeated.

Referring to FIG. 52, the first via insulating layer VIA1′ may be disposed on the inorganic layer IF and the first conductive layers CDL1. The planar size of each of the sub-holes SHL and the planar size of each of the first holes HL1 may be substantially equal to each other. Accordingly, the first conductive layers CDL1 may not contact the substrate SUB. However, the planar size of each of the holes formed in the first via insulating layer VIA1′ may be smaller than the planar size of each of the holes HL formed in the inorganic layer IF. For example, the first via insulating layer VIA1′ may entirely cover the inorganic layer IF and the first conductive layers CDL1 and may contact the upper surface of the substrate SUB.

Referring to FIG. 53, the second conductive layers CDL2 may be disposed on the first via insulating layer VIA1′. The second conductive layers CDL2 may contact the substrate SUB through the holes formed in the first via insulating layer VIA1′.

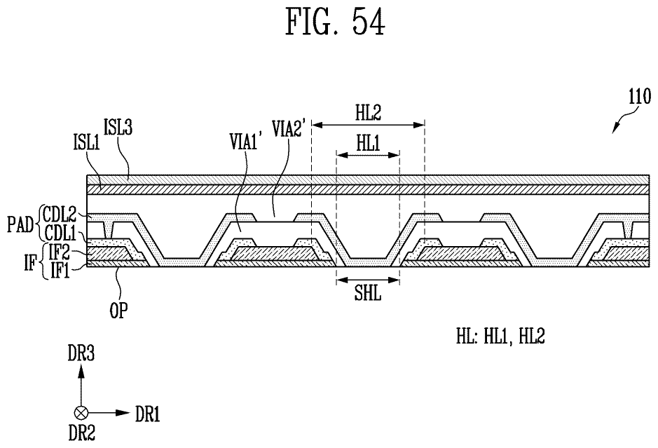

Referring to FIG. 54, a portion of the substrate SUB that overlaps the holes HL of the inorganic layer IF may be removed. For example, a portion of the substrate SUB may be removed to form the opening OP that overlaps the holes HL of the inorganic layer IF. Lower surfaces of the second conductive layers CDL2 included in the pads PAD and a portion of the first via insulating layer VIA1′ may be exposed through the opening OP.

The first via insulating layer VIA1′ containing an organic material may be in direct contact with the second base substrate BS2 containing an organic material, thereby preventing from forming a gap (seam) disposed between an interface of the organic layer and the inorganic layer. Accordingly, the reliability of the display device 110 may be improved.

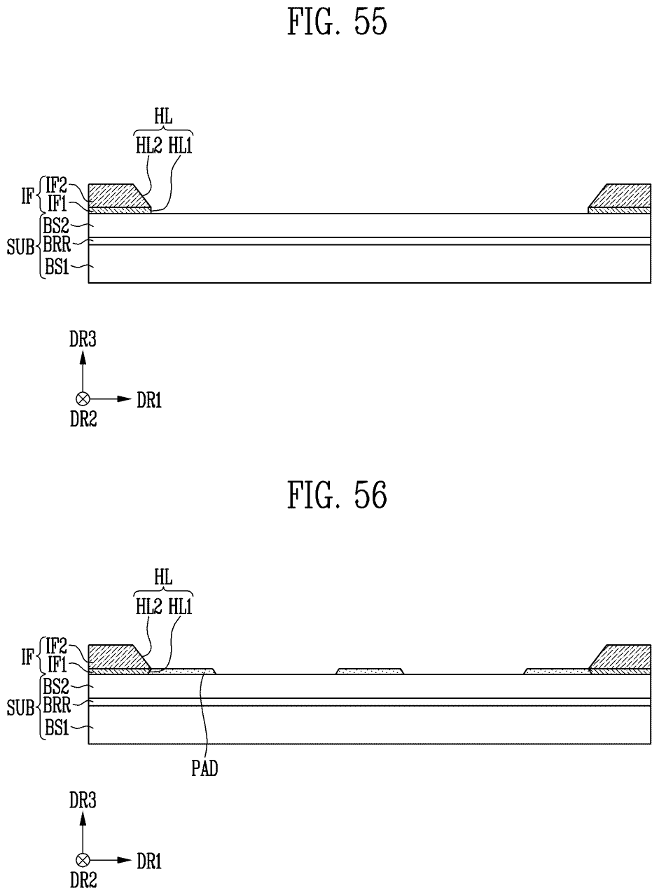

FIGS. 55 to 58 are schematic drawings showing a sixth embodiment of a manufacturing method of a display device. FIGS. 55 to 58 are schematic drawings showing another embodiment of FIGS. 30 to 36.

FIGS. 55 to 58 illustrate a manufacturing method of the display device 111 according to the embodiment described above with reference to FIG. 18. Duplicate description is briefly explained or not repeated.

Referring to FIG. 55, the inorganic layer IF may be disposed on the substrate SUB. A first inorganic layer IF1 may be disposed on the substrate SUB. A first hole HL1 may be formed in the first inorganic layer IF1. A second inorganic layer IF2 may be disposed on the first inorganic layer IF1. A second hole HL2 may be formed in the second inorganic layer IF2. The first hole HL1 and the second hole HL2 may overlap each other to form one hole HL in the third direction DR3. The disclosure is not limited thereto, and one hole HL for every n pads PAD (where n is a natural number of 2 or more) may be formed in the inorganic layer IF. Accordingly, two or more holes HL may be formed in the inorganic layer IF.

Referring to FIG. 56, the pads PAD may be formed on the substrate SUB. The pads PAD may overlap the hole HL and may contact the upper surface of the substrate SUB.

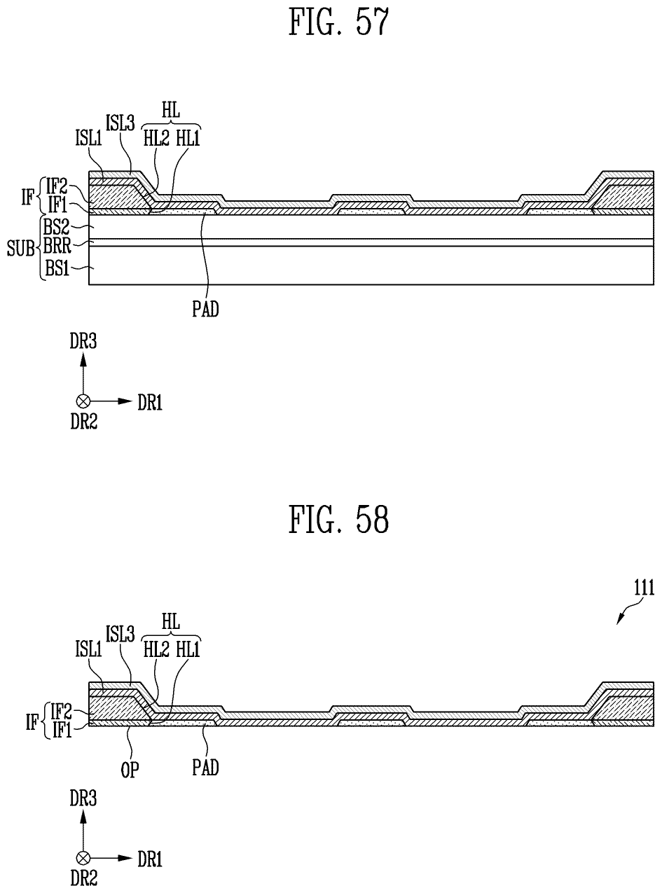

Referring to FIG. 57, the first insulating layer ISL1 and the third insulating layer ISL3 may be disposed on the pads PAD and the inorganic layer IF. The first insulating layer ISL1 and the third insulating layer ISL3 may cover the pads PAD and the inorganic layer IF.

Referring to FIG. 58, a portion of the substrate SUB that overlaps the hole HL of the inorganic layer IF may be removed. For example, a portion of the substrate SUB may be removed to form the opening OP that overlaps the hole HL of the inorganic layer IF. Lower surfaces of the pads PAD may be exposed through the opening OP. The pads PAD exposed through the opening OP may be electrically connected to the circuit board CB of FIG. 6.

The technical idea of the present disclosure has been specifically described according to the embodiments, but it should be noted that the foregoing embodiments are provided only for illustration while not limiting the present disclosure. It will be understood by those skilled in the art that various changes in form and details may be made therein without departing from the scope of the disclosure.

The technical scope of the present disclosure may be determined by the technical scope of the accompanying claims. All changes or modifications that come in the meaning and range of the claims and their equivalents will be interpreted as including the range of the disclosure.

What is claimed is:

1. A display device comprising:
a substrate including an opening;
a light emitting element disposed on the substrate;
an inorganic layer disposed between the substrate and the light emitting element and including a plurality of holes overlapping the opening in a thickness direction;
pads disposed between the inorganic layer and the light emitting element and partially exposed through the holes respectively; and
a circuit board at least partially disposed in the opening, spaced apart from the pads and the light emitting element with the inorganic layer interposed between the circuit board, and the pads and the light emitting element, and electrically connected to the pads exposed through the holes.

2. The display device of claim 1, further comprising:
a conductive ink layer in direct contact with each of the pads and the circuit board.

3. The display device of claim 2, wherein
a protective resin layer covers the conductive ink layer.

4. The display device of claim 1, further comprising:
signal lines electrically connecting the pads and the light emitting element.

5. The display device of claim 1, further comprising:
an insulating layer disposed on the inorganic layer and the pads and entirely covering upper surfaces of the pads.

6. The display device of claim 1, wherein the inorganic layer includes:
a first inorganic layer contacting an upper surface of the substrate; and
a second inorganic layer disposed on the first inorganic layer.

7. The display device of claim 6, wherein
the first inorganic layer includes a plurality of first holes,
the second inorganic layer includes a plurality of second holes overlapping the plurality of first holes respectively in the thickness direction, and
the first holes and the second holes that overlap each other constitute the holes respectively.

8. The display device of claim 7, wherein a planar size of each of the first holes is smaller than a planar size of each of the second holes.

9. The display device of claim 1, wherein the pads include:
first conductive layers contacting an upper surface of the inorganic layer and partially exposed through the holes respectively; and
second conductive layers respectively disposed on the first conductive layers and respectively overlapping the first conductive layers.

10. The display device of claim 1, wherein the pads include:
first conductive layers contacting an upper surface of the inorganic layer and including sub-holes overlapping the holes respectively; and
second conductive layers respectively disposed on the first conductive layers and partially exposed through the holes and the sub-holes respectively.

11. A manufacturing method of a display device comprising:
forming an inorganic layer disposed on a substrate;
forming a plurality of holes in the inorganic layer;
forming pads that respectively overlap the holes on the inorganic layer;
forming a light emitting element disposed on the inorganic layer;
forming an opening overlapping the holes in the substrate; and
providing a circuit board that is at least partially disposed in the opening, is spaced apart from the pads and the light emitting element with the inorganic layer interposed between the circuit board, and the pads and the light emitting element, and is electrically connected to the pads exposed through the holes.

12. The manufacturing method of claim 11, further comprising:
forming a conductive ink layer which is in direct contact with each of the pads and the circuit board.

13. The manufacturing method of claim 12, further comprising:
forming a protective resin layer to cover the conductive ink layer.

14. The manufacturing method of claim 11, further comprising:
before forming the light emitting element,
forming signal lines, wherein
the signal lines connect the pads and the light emitting element.

15. The manufacturing method of claim 11, further comprising:
forming an insulating layer disposed on the inorganic layer and the pads to entirely cover upper surfaces of the pads.

16. The manufacturing method of claim 11, wherein the inorganic layer includes a first inorganic layer and a second inorganic layer, and
the forming of the inorganic layer includes:
forming a first inorganic layer to contact an upper surface of the substrate;
forming a plurality of first holes in the first inorganic layer;
forming a second inorganic layer on the first inorganic layer; and
forming a plurality of second holes overlapping the first holes respectively in the second inorganic layer.

17. The manufacturing method of claim 16, wherein the first holes and the second holes, which overlap each other, form the holes in a thickness direction, respectively.

18. The manufacturing method of claim 17, wherein a planar size of each of the first holes is smaller than a planar size of each of the second holes.

19. The manufacturing method of claim 11, wherein the pads include first conductive layers and second conductive layers, and
the forming the pads include:
forming a first preliminary conductive layer overlapping the holes on an upper surface of the inorganic layer;
patterning the first preliminary conductive layer to form first conductive layers overlapping the holes respectively;
forming a second preliminary conductive layer on the first conductive layers; and
patterning the second preliminary conductive layer to form second conductive layers overlapping the first conductive layers respectively.

20. The manufacturing method of claim 11, wherein
the pads include first conductive layers and second conductive layers, and
the forming of the pads includes:
forming a first preliminary conductive layer overlapping the holes on an upper surface of the inorganic layer;
patterning the first preliminary conductive layer to form first conductive layers overlapping the holes respectively and sub-holes overlapping the holes respectively in the first conductive layers;
forming a second preliminary conductive layer on the first conductive layers; and
patterning the second preliminary conductive layer to form second conductive layers overlapping the sub-holes respectively.
